(19) United States
(12) Patent Application Publication
(10) Pub. No.: US 2022/0140567 A1
(43) Pub. Date: May 5, 2022

(54) SEMICONDUCTOR LASER DEVICE

(71) Applicant: ROHM CO., LTD., Kyoto (JP)

(72) Inventors: Hideyuki UTSUMI, Kyoto (JP); Sho KAWAKAMI, Kyoto (JP); Yoshinori TANAKA, Kyoto (JP)

(73) Assignee: ROHM CO., LTD., Kyoto (JP)

(21) Appl. No.: 17/430,369

(22) PCT Filed: Nov. 29, 2019
(86) PCT No.: PCT/JP2019/046855

§ 371 Date: Aug. 12, 2021

(30) Foreign Application Priority Data
Mar. 8, 2019 (JP) 2019-042890

(51) Int. Cl. H01S 5/02345; H01S 5/227; H01S 5/042

(52) U.S. Cl. CPC H01S 5/02345; H01S 5/04256; H01S 5/227

(57) ABSTRACT

A semiconductor laser device includes a semiconductor layer that includes a light emitting region having a first width and a pad region formed in a region outside the light emitting region and having a second width exceeding the first width, an insulating layer that covers the light emitting region and the pad region, and a wiring electrode that has an internal connection region penetrating through the insulating layer and electrically connected to the light emitting region and an external connection region that covers the pad region across the insulating layer and is to be externally connected to a lead wire.

### TECHNICAL FIELD

The present invention relates to a semiconductor laser device.

### BACKGROUND ART

Patent Literature 1 discloses a semiconductor laser device including a semiconductor layer, an insulating layer that is formed on the semiconductor layer, and an electrode that is formed on the insulating layer. The semiconductor layer has a light emitting region in which laser light is generated and a non-light emitting region outside the light emitting region. The insulating layer covers the light emitting region and the non-light emitting region. The electrode covers the light emitting region and the non-light emitting region across the insulating layer, penetrates through the insulating layer, and is electrically connected to the light emitting region. A bonding wire (lead wire) is to be externally connected to a portion of the electrode that covers the light emitting region.

### CITATION LIST

### Patent Literature

Patent Literature 1: Japanese Patent Application Publication No. 2012-227313

### SUMMARY OF INVENTION

### Technical Problem

Directivity of laser light can be improved by reducing the light emitting region. However, in this case, it becomes difficult to secure a connection region of the lead wire on the light emitting region. There is also a possibility of occurrence of a defect in the light emitting region due to external force and stress during connecting of the lead wire.

A preferred embodiment of the present invention provides a semiconductor laser device that enables reduction of a light emitting region to be achieved appropriately without being restricted in design due to a lead wire.

### Solution to Problem

A preferred embodiment of the present invention provides a semiconductor laser device including a semiconductor layer that includes a light emitting region having a first width and a pad region formed in a region outside the light emitting region and having a second width exceeding the first width, an insulating layer that covers the light emitting region and the pad region, and a wiring electrode that has an internal connection region penetrating through the insulating layer and electrically connected to the light emitting region and an external connection region that covers the pad region across the insulating layer and is to be externally connected to a lead wire.

According to this semiconductor laser device, reduction of the light emitting region can be achieved appropriately without being restricted in design due to the lead wire.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a perspective view of a semiconductor laser device according to a first preferred embodiment of the present invention shown together with lead wires that are connected to the semiconductor laser device.

FIG. 2 is a plan view of the semiconductor laser device shown in FIG. 1.

FIG. 3 is a sectional view taken along line III-III shown in FIG. 2.

FIG. 4 is an enlarged sectional view of a light emitting region shown in FIG. 3.

FIG. 5 is an enlarged sectional view of a pad region shown in FIG. 3.

FIG. 6 is an enlarged sectional view of an outer region shown in FIG. 3.

FIG. 7 is a diagram for describing a structure example of light emitting unit layers.

FIG. 8 is a diagram for describing a structure example of tunnel junction layers.

FIG. 9 is a perspective view of a semiconductor laser device according to a second preferred embodiment of the present invention shown together with the lead wires that are connected to the semiconductor laser device.

FIG. 10 is a plan view of the semiconductor laser device shown in FIG. 9.

FIG. 11 is a sectional view taken along line XI-XI shown in FIG. 10.

FIG. 12 is a perspective view of a semiconductor laser device according to a third preferred embodiment of the present invention shown together with the lead wires that are connected to the semiconductor laser device.

FIG. 13 is an exploded perspective view of a package according to a first configuration example.

FIG. 14 is a plan view of a package according to a second configuration example.

FIG. 15 is a sectional view taken along line XV-XV shown in FIG. 14.

FIG. 16 is a plan view of a package according to a third configuration example.

FIG. 17 is a bottom view of the package shown in FIG. 16.

FIG. 18 is a sectional view taken along line XVIII-XVIII shown in FIG. 17.

### DESCRIPTION OF EMBODIMENTS

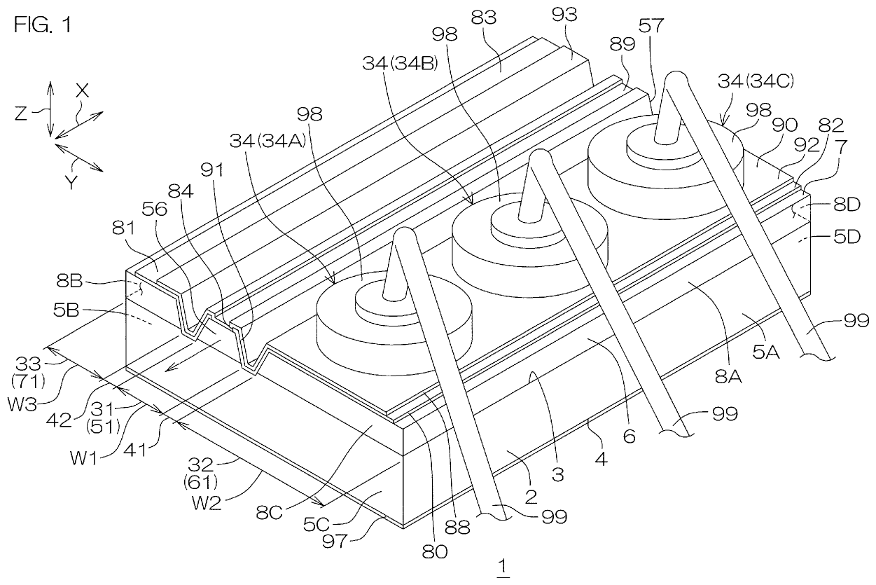

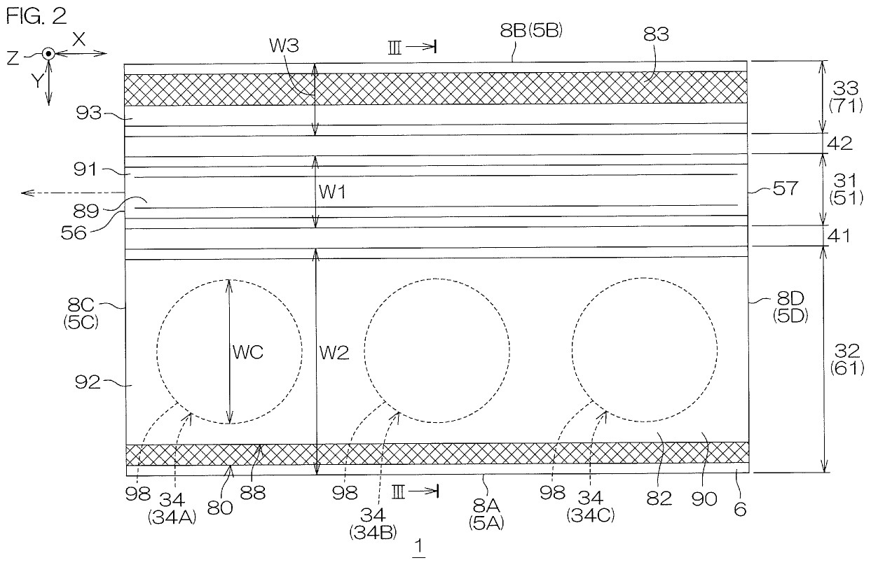

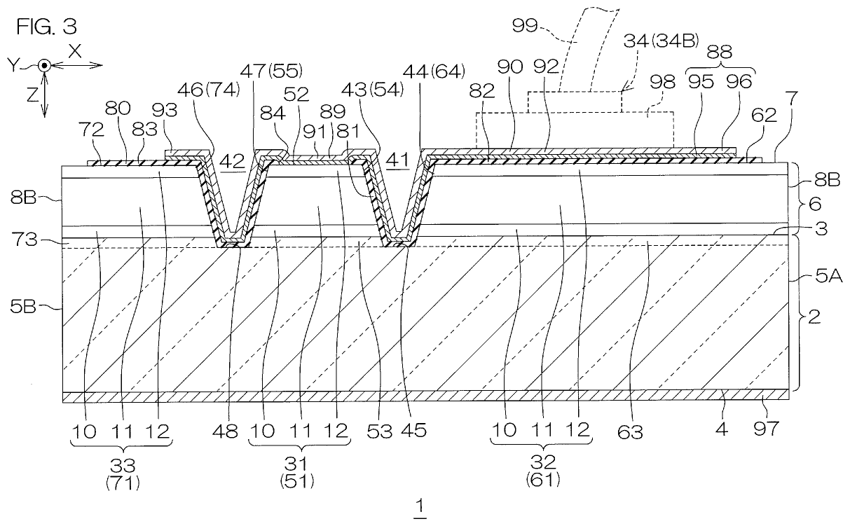

FIG. 1 is a perspective view of a semiconductor laser device 1 according to a first preferred embodiment of the present invention shown together with lead wires 34 that are connected to the semiconductor laser device 1. FIG. 2 is a plan view of the semiconductor laser device 1 shown in FIG. 1. FIG. 3 is a sectional view taken along line shown in FIG. 2.

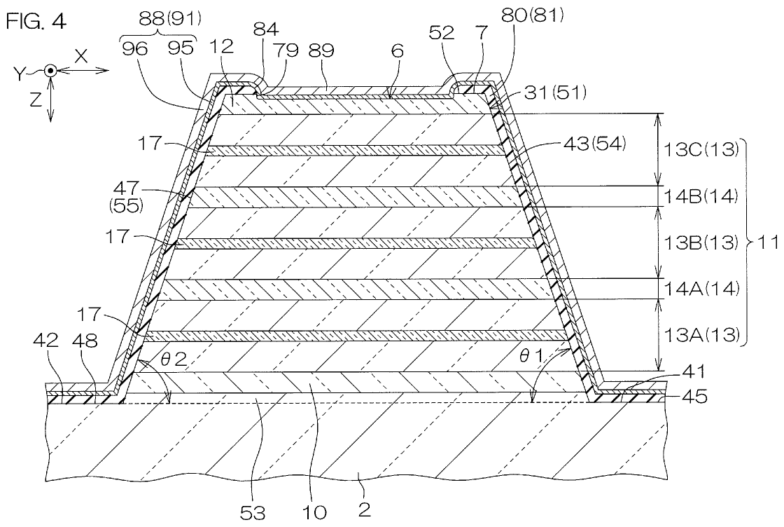

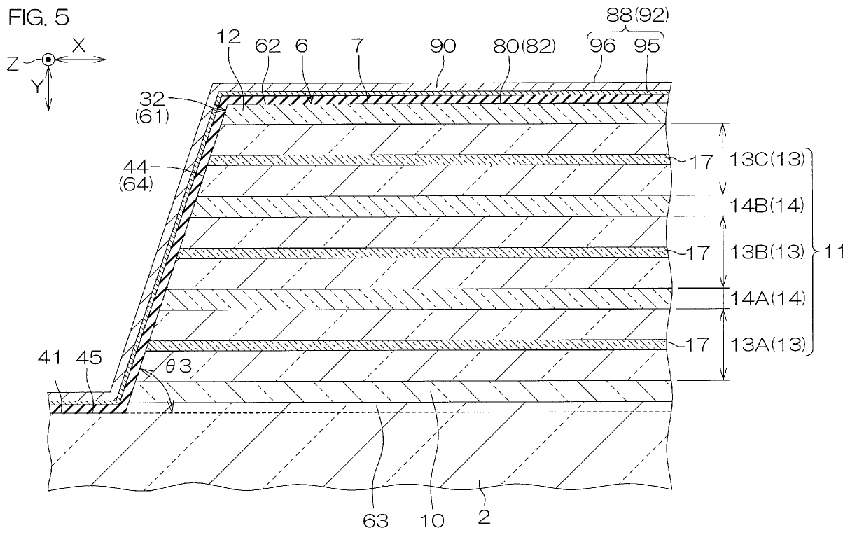

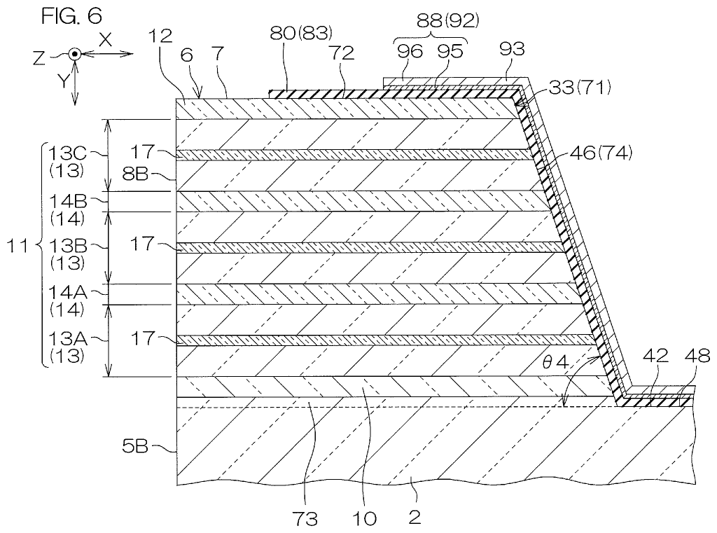

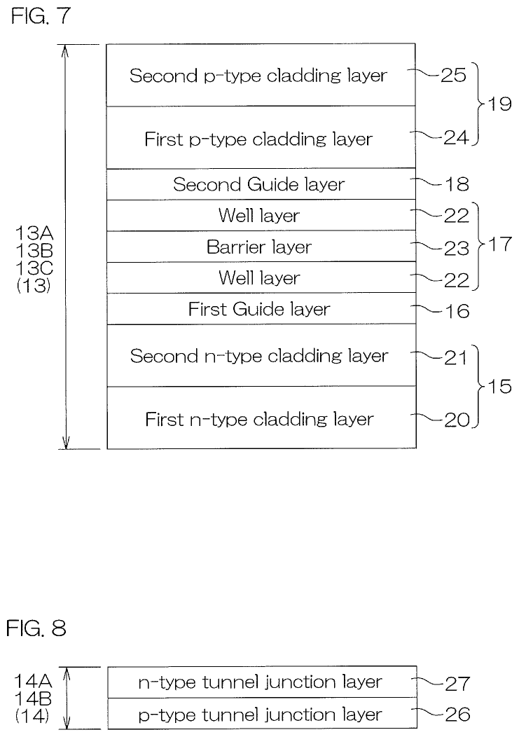

FIG. 4 is an enlarged sectional view of a light emitting region 31 shown in FIG. 3. FIG. 5 is an enlarged sectional view of a pad region 32 shown in FIG. 3. FIG. 6 is an enlarged sectional view of an outer region 33 shown in FIG. 3. FIG. 7 is a diagram for describing a structure example of light emitting unit layers 13. FIG. 8 is a diagram for describing a structure example of tunnel junction layers 14.

Referring to FIG. 1 to FIG. 3, the semiconductor laser device 1 includes a substrate 2 that is formed to a rectangular parallelepiped shape. In this embodiment, the substrate 2 is constituted of a GaAs (gallium arsenide) substrate doped with an n-type impurity. The n-type impurity may include at least one type of material among Si (silicon), Te (tellurium), and Se (selenium).

The substrate 2 includes a first substrate main surface 3 at one side, a second substrate main surface 4 at another side, and substrate side surfaces 5A, 5B, 5C, and 5D that connect the first substrate main surface 3 and the second substrate main surface 4. The first substrate main surface 3 and the second substrate main surface 4 are formed to quadrilateral shapes (rectangular shapes in this embodiment) in a plan view as viewed from a normal direction Z thereto (hereinafter referred to simply as “plan view”).

The substrate side surfaces 5A to 5D include a first substrate side surface 5A, a second substrate side surface 5B, a third substrate side surface 5C, and a fourth substrate side surface 5D. The first substrate side surface 5A and the second substrate side surface 5B form long sides of the substrate 2. The first substrate side surface 5A and the second substrate side surface 5B extend along a first direction X and face each other in a second direction Y that intersects the first direction X. More specifically, the second direction Y is orthogonal to the first direction X.

The third substrate side surface 5C and the fourth substrate side surface 5D form short sides of the substrate 2. The third substrate side surface 5C and the fourth substrate side surface 5D extend along the second direction Y and face each other in the first direction X. Preferably, at least the substrate side surface 5C and the substrate side surface 5D among the substrate side surfaces 5A to 5D are mirror-finished. All of the substrate side surfaces 5A to 5D may be mirror-finished. The substrate side surfaces 5A to 5D may be cleavage surfaces instead.

A thickness of the substrate 2 may be not less than 50 μm and not more than 350 μm. The thickness may be not less than 50 μm and not more than 100 μm, not less than 100 μm and not more than 150 μm, not less than 150 μm and not more than 200 μm, not less than 200 μm and not more than 250 μm, not less than 250 μm and not more than 300 μm, or not less than 300 μm and not more than 350 μm.

A length L1 of the first substrate side surface 5A (second substrate side surface 5B) may be not less than 200 μm and not more than 1000 μm. The length L1 may be not less than 200 μm and not more than 400 μm, not less than 400 μm and not more than 600 μm, not less than 600 μm and not more than 800 μm, or not less than 800 μm and not more than 1000 μm. In this embodiment, the length L1 is not less than 500 μm and not more than 700 μm.

A length L2 of the third substrate side surface 5C (fourth substrate side surface 5D) may be not less than 50 μm and not more than 600 μm. The length L2 may be not less than 50 μm and not more than 100 μm, not less than 100 μm and not more than 200 μm, not less than 200 μm and not more than 300 μm, not less than 300 μm and not more than 400 μm, not less than 400 μm and not more than 500 μm, or not less than 500 μm and not more than 600 μm. In this embodiment, the length L2 is not less than 300 μm and not more than 500 μm.

The semiconductor laser device 1 further includes a semiconductor layer 6 that is formed on the first substrate main surface 3. The semiconductor layer 6 is formed on the first substrate main surface 3 by an epitaxial growth method. The semiconductor layer 6 generates laser light. The semiconductor layer 6 generates laser light having a peak emission wavelength in a range of not less than 800 nm and not more than 1000 nm. That is, the semiconductor layer 6 emits laser light in an infrared region.

The semiconductor layer 6 includes a semiconductor main surface 7 and semiconductor side surfaces 8A, 8B, 8C, and 8D. The semiconductor main surface 7 is formed to a quadrilateral shape (a rectangular shape in this embodiment) in plan view. The semiconductor side surfaces 8A to 8D include a first semiconductor side surface 8A, a second semiconductor side surface 8B, a third semiconductor side surface 8C, and a fourth semiconductor side surface 8D. The semiconductor side surfaces 8A to 8D are continuous to the substrate side surfaces 5A to 5D. More specifically, the semiconductor side surfaces 8A to 8D are formed flush with the substrate side surfaces 5A to 5D.

Referring to FIG. 3 to FIG. 6, the semiconductor layer 6 has a laminated structure that includes an n-type buffer layer 10, a light emitting layer 11, and a p-type contact layer 12. The n-type buffer layer 10 supplies electrons to the light emitting layer 11. The p-type contact layer 12 supplies holes to the light emitting layer 11. The light emitting layer 11 generates laser light by combination of the holes and the electrons.

The n-type buffer layer 10 is laminated on the first substrate main surface 3. The n-type buffer layer 10 includes GaAs (gallium arsenide) doped with an n-type impurity. The n-type impurity may include at least one type of material among Si (silicon), Te (tellurium), and Se (selenium). An n-type impurity concentration of the n-type buffer layer 10 may be not less than 1×10¹⁸ cm⁻³ and not more than 1×10¹⁹ cm⁻³.

The light emitting layer 11 is laminated on the n-type buffer layer 10. In this embodiment, the light emitting layer 11 includes a plurality (three in this embodiment) of light emitting unit layers 13 and a plurality (two in this embodiment) of tunnel junction layers 14. The light emitting unit layers 13 generate light by the combination of the holes and the electrons. The tunnel junction layers 14 generate a tunnel current due to a tunnel effect and supplies the tunnel current to the light emitting unit layers 13.

The plurality of light emitting unit layers 13 include a first light emitting unit layer 13A, a second light emitting unit layer 13B, and a third light emitting unit layer 13C that are laminated in that order from the n-type buffer layer 10 side.

Referring to FIG. 7, the first light emitting unit layer 13A, the second light emitting unit layer 13B, and the third light emitting unit layer 13C each have a laminated structure that includes an n-type cladding layer 15 (first semiconductor layer), a first guide layer 16, an active layer 17, a second guide layer 18, and a p-type cladding layer 19 (second semiconductor layer) that are laminated in that order from the substrate 2 side.

The n-type cladding layer 15 includes AlGaAs (aluminum gallium arsenide) doped with an n-type impurity. The n-type impurity may include at least one type of material among Si (silicon), Te (tellurium), and Se (selenium). An n-type impurity concentration of the n-type cladding layer 15 may be not less than 1×10¹⁷ cm⁻³ and not more than 1×10¹⁹ cm⁻³. In this embodiment, the n-type cladding layer 15 includes a first n-type cladding layer 20 and a second n-type cladding layer 21 that are laminated in that order from the substrate 2 side.

The first n-type cladding layer 20 includes Al_{A}Ga_{(1-A)}As having a first Al composition A. The first Al composition A may be not less than 0.4 and not more than 0.6. The first Al composition A may be not less than 0.4 and not more than 0.45, not less than 0.45 and not more than 0.5, not less than 0.5 and not more than 0.55, or not less than 0.55 and not more than 0.6. An n-type impurity concentration of the first n-type cladding layer 20 may be not less than 5×10¹⁷ cm⁻³ and not more than 1×10¹⁹ cm⁻³.

A thickness of the first n-type cladding layer 20 may be not less than 5000 Å and not more than 10000 Å. The thickness of the first n-type cladding layer 20 may be not less than 5000 Å and not more than 6000 Å, not less than 6000 Å and not more than 7000 Å, not less than 7000 Å and not more than 8000 Å, not less than 8000 Å and not more than 9000 Å, or not less than 9000 Å and not more than 10000 Å.

The second n-type cladding layer 21 includes Al_{B}Ga_{(1-B)}As having a second Al composition B that differs from the first Al composition A of the first n-type cladding layer 20. More specifically, the second Al composition B is less than the first Al composition A (B<A). The second Al composition B may be not less than 0.2 and not more than 0.4. The second Al composition B may be not less than 0.2 and not more than 0.25, not less than 0.25 and not more than 0.3, not less than 0.3 and not more than 0.35, or not less than 0.35 and not more than 0.4.

The second n-type cladding layer 21 has an n-type impurity concentration that differs from the n-type impurity concentration of the first n-type cladding layer 20. More specifically, the n-type impurity concentration of the second n-type cladding layer 21 is less than the n-type impurity concentration of the first n-type cladding layer 20. The n-type impurity concentration of the second n-type cladding layer 21 may be not less than 1×10¹⁷ cm⁻³ and not more than 5×10¹⁸ cm⁻³.

The second n-type cladding layer 21 may have a thickness differing from the thickness of the first n-type cladding layer 20. The second n-type cladding layer 21 may have a thickness that exceeds the thickness of the first n-type cladding layer 20.

The thickness of the second n-type cladding layer 21 may be not less than 7000 Å and not more than 13000 Å. The thickness of the second n-type cladding layer 21 may be not less than 7000 Å and not more than 8000 Å, not less than 8000 Å and not more than 9000 Å, not less than 9000 Å and not more than 10000 Å, not less than 10000 Å and not more than 11000 Å, not less than 11000 Å and not more than 12000 Å, or not less than 12000 Å and not more than 13000 Å.

The first guide layer 16 includes Al_{C}Ga_{(1-C)}As having a third Al composition C that differs from the Al compositions (first Al composition A and second Al composition B) of the n-type cladding layer 15. More specifically, the third Al composition C is less than the Al compositions of the n-type cladding layer 15 (C<B<A).

The third Al composition C may exceed 0 but be not more than 0.2. The third Al composition C may exceed 0 but be not more than 0.05 or be not less than 0.05 and not more than 0.1, not less than 0.1 and not more than 0.15, or not less than 0.15 and not more than 0.2. The first guide layer 16 may be undoped.

A thickness of the first guide layer 16 is less than the thickness of the first n-type cladding layer 20. The thickness of the first guide layer 16 may be not less than 50 Å and not more than 250 Å. The thickness of the first guide layer 16 may be not less than 50 Å and not more than 100 Å, not less than 100 Å and not more than 150 Å, not less than 150 Å and not more than 200 Å, or not less than 200 Å and not more than 250 Å.

The active layer 17 has a multiple quantum well structure that includes a well layer 22 and a barrier layer 23. In this embodiment, the active layer 17 has a three layer structure that includes a well layer 22, a barrier layer 23, and a well layer 22 that are laminated in that order from the substrate 2 side.

The active layer 17 may have a multiple quantum well structure that includes well layers 22 and barrier layers 23 that are laminated alternately in plural periods (two periods or more). In this case, a lowermost layer of the active layer 17 on the basis of the substrate 2 side may be a well layer 22 or may be a barrier layer 23. An uppermost layer of the active layer 17 may be a well layer 22 or a may be a barrier layer 23.

The well layer 22 includes In_{α}Ga_{(1-α)}As having an In composition a. The In composition a may exceed 0 but be not more than 0.2. The In composition a may exceed 0 but be not more than 0.05 or be not less than 0.05 and not more than 0.1, not less than 0.1 and not more than 0.15, or not less than 0.15 and not more than 0.2. The well layer 22 may be undoped.

A thickness of the well layer 22 may be less than the thickness of the first guide layer 16. The thickness of the well layer 22 may be not less than 10 Å and not more than 150 Å. The thickness of the well layer 22 may be not less than 10 Å and not more than 50 Å, not less than 50 Å and not more than 100 Å, or not less than 100 Å and not more than 150 Å.

The barrier layer 23 includes Al_{D}Ga_{(1-D)}As having a fourth Al composition D that differs from the Al compositions (first Al composition A and second Al composition B) of the n-type cladding layer 15. More specifically, the fourth Al composition D is less than the Al compositions of the n-type cladding layer 15 (D<B<A).

The fourth Al composition D may exceed 0 but be not more than 0.2. The fourth Al composition D may exceed 0 but be not more than 0.05 or be not less than 0.05 and not more than 0.1, not less than 0.1 and not more than 0.15, or not less than 0.15 and not more than 0.2. The barrier layer 23 may be undoped.

The barrier layer 23 may have a thickness differing from the well layer 22. The thickness of the barrier layer 23 may exceed the thickness of the well layer 22 but be less than the thickness of the first guide layer 16. The thickness of the barrier layer 23 may be not less than 20 Å and not more than 200 Å. The thickness of the first guide layer 16 may be not less than 20 Å and not more than 50 Å, not less than 50 Å and not more than 100 Å, not less than 100 Å and not more than 150 Å, or not less than 150 Å and not more than 200 Å.

The second guide layer 18 includes Al_{E}Ga_{(1-E)}As having a fifth Al composition E that differs from the Al compositions (first Al composition A and second Al composition B) of the n-type cladding layer 15. More specifically, the fifth Al composition E is less than the Al compositions of the n-type cladding layer 15 (E<B<A). The fifth Al composition E may exceed 0 but be not more than 0.2.

The fifth Al composition E may exceed 0 but be not more than 0.05 or be not less than 0.05 and not more than 0.1, not less than 0.1 and not more than 0.15, or not less than 0.15 and not more than 0.2. The second guide layer 18 may be undoped.

A thickness of the second guide layer 18 may exceed the thickness of the barrier layer 23. The thickness of the second guide layer 18 may be not less than 50 Å and not more than 250 Å. The thickness of the second guide layer 18 may be not less than 50 Å and not more than 100 Å, not less than 100 Å and not more than 150 Å, not less than 150 Å and not more than 200 Å, or not less than 200 Å and not more than 250 Å.

The p-type cladding layer 19 includes AlGaAs doped with a p-type impurity. The p-type impurity may include C (carbon). A p-type impurity concentration of the p-type cladding layer 19 may be not less than 1×10¹⁷ cm⁻³ and not more than 1×10¹⁹ cm⁻³. In this embodiment, the p-type cladding layer 19 includes a first p-type cladding layer 24 and a second p-type cladding layer 25 that are laminated in that order from the active layer 17 side.

The first p-type cladding layer 24 includes Al_{F}Ga_{(1-F)}As having a sixth Al composition F. The sixth Al composition F may be not less than 0.2 and not more than 0.4. The sixth Al composition F may be not less than 0.2 and not more than 0.25, not less than 0.25 and not more than 0.3, not less than 0.3 and not more than 0.35, or not less than 0.35 and not more than 0.4. A p-type impurity concentration of the first p-type cladding layer 24 may be not less than 1×10¹⁷ cm⁻³ and not more than 5×10¹⁸ cm⁻³.

A thickness of the first p-type cladding layer 24 may be not less than 8000 Å and not more than 15000 Å. The thickness of the first p-type cladding layer 24 may be not less than 8000 Å and not more than 9000 Å, not less than 9000 Å and not more than 10000 Å, not less than 10000 Å and not more than 11000 Å, not less than 11000 Å and not more than 12000 Å, not less than 12000 Å and not more than 13000 Å, not less than 13000 Å and not more than 14000 Å, or not less than 14000 Å and not more than 15000 Å.

The second p-type cladding layer 25 includes Al_{G}Ga_{(1-G)}As having a seventh Al composition G that differs from the sixth Al composition F of the first p-type cladding layer 24. More specifically, the seventh Al composition G exceeds the sixth Al composition F (F<G). The seventh Al composition G may be not less than 0.4 and not more than 0.6. The seventh Al composition G may be not less than 0.4 and not more than 0.45, not less than 0.45 and not more than 0.5, not less than 0.5 and not more than 0.55, or not less than 0.55 and not more than 0.6.

The second p-type cladding layer 25 has a p-type impurity concentration that differs from the p-type impurity concentration of the first p-type cladding layer 24. More specifically, the p-type impurity concentration of the second p-type cladding layer 25 exceeds the p-type impurity concentration of the first p-type cladding layer 24. The p-type impurity concentration of the second p-type cladding layer 25 may be not less than 5×10¹⁷ cm⁻³ and not more than 1×10¹⁹ cm⁻³.

The second p-type cladding layer 25 may have a thickness differing from the thickness of the first p-type cladding layer 24. The second p-type cladding layer 25 may have a thickness less than the thickness of the first p-type cladding layer 24.

The thickness of the second p-type cladding layer 25 may be not less than 4000 Å and not more than 10000 Å. The thickness of the second p-type cladding layer 25 may be not less than 4000 Å and not more than 5000 Å, not less than 5000 Å and not more than 6000 Å, not less than 6000 Å and not more than 7000 Å, not less than 7000 Å and not more than 8000 Å, not less than 8000 Å and not more than 9000 Å, or not less than 9000 Å and not more than 10000 Å.

Referring to FIG. 8, the plurality of tunnel junction layers 14 include a first tunnel junction layer 14A and a second tunnel junction layer 14B. The first tunnel junction layer 14A is interposed in a region between the first light emitting unit layer 13A and the second light emitting unit layer 13B. The second tunnel junction layer 14B is interposed in a region between the second light emitting unit layer 13B and the third light emitting unit layer 13C.

The first tunnel junction layer 14A and the second tunnel junction layer 14B each have a p-type tunnel junction layer 26 and an n-type tunnel junction layer 27 that are laminated in that order from the substrate 2 side. The first tunnel junction layer 14A and the second tunnel junction layer 14B are interposed in regions between the plurality of light emitting unit layers 13A to 130 in a mode where the p-type tunnel junction layer 26 is electrically connected to the p-type cladding layer 19 and the n-type tunnel junction layer 27 is electrically connected to the n-type cladding layer 15.

The p-type tunnel junction layer 26 includes GaAs doped with a p-type impurity. The p-type impurity may include C (carbon). The p-type tunnel junction layer 26 has a p-type impurity concentration that differs from the p-type impurity concentration of the p-type cladding layer 19. More specifically, the p-type impurity concentration of the p-type tunnel junction layer 26 exceeds the p-type impurity concentration of the p-type cladding layer 19. The p-type impurity concentration of the p-type tunnel junction layer 26 may be not less than 1×10¹⁸ cm⁻³ and not more than 1×10²⁰ cm⁻³.

A thickness of the p-type tunnel junction layer 26 may be not less than 100 Å and not more than 1000 Å. The thickness of the p-type tunnel junction layer 26 may be not less than 100 Å and not more than 200 Å, not less than 200 Å and not more than 400 Å, not less than 400 Å and not more than 600 Å, not less than 600 Å and not more than 800 Å, or not less than 800 Å and not more than 1000 Å.

The n-type tunnel junction layer 27 includes GaAs doped with an n-type impurity. The n-type impurity may include at least one type of material among Si (silicon), Te (tellurium), and Se (selenium). The n-type tunnel junction layer 27 has an n-type impurity concentration that differs from the n-type impurity concentration of the n-type cladding layer 15. More specifically, the n-type impurity concentration of the n-type tunnel junction layer 27 exceeds the n-type impurity concentration of the n-type cladding layer 15. The n-type impurity concentration of the n-type tunnel junction layer 27 may be not less than 5×10¹⁷ cm⁻³ and not more than 5×10¹⁹ cm⁻³.

A thickness of the n-type tunnel junction layer 27 may be not less than 100 Å and not more than 1000 Å. The thickness of the n-type tunnel junction layer 27 may be not less than 100 Å and not more than 200 Å, not less than 200 Å and not more than 400 Å, not less than 400 Å and not more than 600 Å, not less than 600 Å and not more than 800 Å, or not less than 800 Å and not more than 1000 Å.

Referring to FIG. 3 to FIG. 6, the p-type contact layer 12 is formed on the light emitting layer 11. The semiconductor main surface 7 of the semiconductor layer 6 is formed by the p-type contact layer 12. The p-type contact layer 12 includes GaAs doped with a p-type impurity. The p-type impurity may be C (carbon).

The p-type contact layer 12 has a p-type impurity concentration that differs from the p-type impurity concentration of the p-type cladding layer 19. More specifically, the p-type impurity concentration of the p-type contact layer 12 exceeds the p-type impurity concentration of the p-type cladding layer 19. The p-type impurity concentration of the p-type contact layer 12 may be not less than 5×10¹⁸ cm⁻³ and not more than 1×10²⁰ cm⁻³.

A thickness of the p-type contact layer 12 may be not less than 1000 Å and not more than 5000 Å. The thickness of the p-type contact layer 12 may be not less than 1000 Å and not more than 2000 Å, not less than 2000 Å and not more than 3000 Å, not less than 3000 Å and not more than 4000 Å, or not less than 4000 Å and not more than 5000 Å.

Referring to FIG. 1 to FIG. 6, the semiconductor layer 6 includes a light emitting region 31, a pad region 32, and an outer region 33. The light emitting region 31 is a region in which laser light is generated. The pad region 32 and the outer region 33 are regions in which laser light is not generated. The pad region 32 is a region to which the lead wires 34 are to be connected. The outer region 33 is a region to which the lead wires 34 are not to be connected.

The light emitting region 31 is formed as a band extending along the first direction X. The light emitting region 31 is formed shifted in the second direction Y with respect to a center of the substrate 2 in plan view. In this embodiment, the light emitting region 31 is biased to the second substrate side surface 5B side from the center of the substrate 2 in plan view.

The light emitting region 31 has a first width W1 in the second direction Y. The light emitting region 31 has a first area S1 in plan view. The first area S1 has a value obtained by multiplying the length L1 of the first substrate side surface 5A by the first width W1 (L1×W1).

The first width W1 may be not less than 40 μm and not more than 100 μm. The first width W1 may be not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, or not less than 90 μm and not more than 100 μm. The first width W1 is preferably not less than 50 μm and not more than 80 μm.

The pad region 32 is formed in a region at the first substrate side surface 5A side with respect to the light emitting region 31. The pad region 32 is formed as a band extending along the first direction X. The pad region 32 has a second width W2 in the second direction Y that exceeds the first width W1 (W1<W2). The pad region 32 has a second area S2 in plan view that exceeds the first area S1 (S1<S2). The second area S2 has a value obtained by multiplying the length L1 of the first substrate side surface 5A by the second width W2 (L1×W2).

The second width W2 is preferably not less than ¼ and not more than ⅔ of the length L2 of the third substrate side surface 5C. The second width W2 is preferably not less than 1.5 times and not more than 4 times the first width W1. The second width W2 may be not less than 150 μm and not more than 300 μm. The second width W2 may be not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, or not less than 275 μm and not more than 300 μm. The second width W2 is preferably not less than 150 μm and not more than 250 μm.

The outer region 33 is formed in a region at the second substrate side surface 5B side with respect to the light emitting region 31. The outer region 33 is formed as a band extending along the first direction X. The outer region 33 has a third width W3 in the second direction Y. The magnitude of the third width W3 is arbitrary and is adjusted in accordance with the magnitude of the first width W1 and the magnitude of the second width W2.

From a standpoint of securing the pad region 32, the third width W3 is preferably less than the second width W2 (W3<W2). The third width W3 may be not less than the first width W1 (W1≤W3) or may be less than the first width W1 (W3<W2). In this embodiment, the third width W3 is adjusted to be not less than the first width W1 but less than the second width W2 (W1≤W3<W2).

The outer region 33 has a third area S3 in plan view that is not less than the first area S1 but less than the second area S2 (S1≤S3<S2). The third area S3 has a value obtained by multiplying the length L1 of the first substrate side surface 5A by the third width W3 (L1×W3).

The third width W3 may be not less than 25 μm but less than 150 μm. The third width W3 may be not less than 25 μm and not more than 50 μm, not less than 50 μm and not more than 75 μm, not less than 75 μm and not more than 100 μm, not less than 100 μm and not more than 125 μm, or not less than 125 μm and not more than 150 μm. The third width W3 is preferably not less than 50 μm and not more than 100 μm.

The light emitting region 31, the pad region 32, and the outer region 33 are respectively demarcated by a first trench 41 and a second trench 42 that are formed in the semiconductor main surface 7 of the semiconductor layer 6. The first trench 41 is formed in a region between the light emitting region 31 and the pad region 32. The second trench 42 is formed in a region between the light emitting region 31 and the outer region 33.

The first trench 41 and the second trench 42 are formed by removing unnecessary portions of the semiconductor layer 6 by an etching method via a resist mask. The etching method may be a wet etching method or a dry etching method.

The first trench 41 is formed as a band extending along the first direction X in plan view. The first trench 41 is in communication with the third semiconductor side surface 8C and the fourth semiconductor side surface 8D. The first trench 41 penetrates through the p-type contact layer 12 and the light emitting layer 11 such as to at least reach the second n-type cladding layer 21 of the lowermost light emitting unit layer 13 (first light emitting unit layer 13A). In this embodiment, the first trench 41 penetrates through the p-type contact layer 12, the light emitting layer 11, and the n-type buffer layer 10 and reaches the substrate 2.

The first trench 41 has a first side wall 43 at the light emitting region 31 side, a second side wall 44 at the pad region 32 side, and a bottom wall 45 that connects the first side wall 43 and the second side wall 44. The p-type contact layer 12, the light emitting layer 11, the n-type buffer layer 10, and the substrate 2 are exposed from the first side wall 43 and the second side wall 44. The substrate 2 is exposed from the bottom wall 45. The first trench 41 is formed to a convergent shape that narrows in opening width from the semiconductor main surface 7 toward the bottom wall 45.

The second trench 42 is formed as a band extending along the first direction X in plan view. The second trench 42 is in communication with the third semiconductor side surface 8C and the fourth semiconductor side surface 8D. The second trench 42 penetrates through the p-type contact layer 12 and the light emitting layer 11 such as to at least reach the second n-type cladding layer 21 of the lowermost light emitting unit layer 13 (first light emitting unit layer 13A). In this embodiment, the second trench 42 penetrates through the p-type contact layer 12, the light emitting layer 11, and the n-type buffer layer 10 and reaches the substrate 2.

The second trench 42 has a first side wall 46 at the outer region 33 side, a second side wall 47 at the light emitting region 31 side, and a bottom wall 48 that connects the first side wall 46 and the second side wall 47. The p-type contact layer 12, the light emitting layer 11, the n-type buffer layer 10, and the substrate 2 are exposed from the first side wall 46 and the second side wall 47. The substrate 2 is exposed from the bottom wall 48. The second trench 42 is formed to a convergent shape that narrows in opening width from the semiconductor main surface 7 toward the bottom wall 48.

The first width W1 of the light emitting region 31 is defined by a width in the second direction Y between the bottom wall 45 of the first trench 41 and the bottom wall 48 of the second trench 42. The second width W2 of the pad region 32 is defined by a width in the second direction Y between the bottom wall 45 of the first trench 41 and the first semiconductor side surface 8A (first substrate side surface 5A).

The third width W3 of the outer region 33 is defined by a width in the second direction Y between the bottom wall 48 of the second trench 42 and the second semiconductor side surface 8B (second substrate side surface 5B). The light emitting region 31, the pad region 32, and the outer region 33 are specified specifically by the following structures.

The light emitting region 31 has a mesa structure 51 of mesa shape (ridge shape) that projects from the first substrate main surface 3 toward an opposite side to the second substrate main surface 4. The mesa structure 51 is demarcated by the first trench 41 and the second trench 42. The mesa structure 51 includes an apex portion 52, a base portion 53, a first side wall 54 at the pad region 32 side and a second side wall 55 at the outer region 33 side.

The apex portion 52 is formed by a portion of the semiconductor main surface 7. That is, the apex portion 52 is formed by the p-type contact layer 12. The apex portion 52 is formed parallel to the first substrate main surface 3 of the substrate 2. The base portion 53 is preferably positioned at the substrate 2 side at least with respect to the light emitting layer 11. In this embodiment, the base portion 53 is formed by the substrate 2. The base portion 53 may instead be formed by the n-type buffer layer 10.

The first side wall 54 is formed by the first side wall 43 of the first trench 41. The second side wall 55 is formed by the second side wall 47 of the second trench 42. The first side wall 54 and the second side wall 55 each connect the apex portion 52 and the base portion 53. The first side wall 54 and the second side wall 55 are each formed by the p-type contact layer 12, the light emitting layer 11, the n-type buffer layer 10, and the substrate 2.

The mesa structure 51 further includes a first end surface 56 and a second end surface 57. The first end surface 56 is exposed from the third substrate side surface 5C. More specifically, the first end surface 56 is formed flush with the third substrate side surface 5C. The first end surface 56 is mirror-finished. In this embodiment, the first end surface 56 forms a single cleavage surface with the third substrate side surface 5C.

The second end surface 57 is exposed from the fourth substrate side surface 5D. More specifically, the second end surface 57 is formed flush with the fourth substrate side surface 5D. The second end surface 57 is mirror-finished. In this embodiment, the second end surface 57 forms a single cleavage surface with the fourth substrate side surface 5D.

The first end surface 56 and the second end surface 57 form resonator end surfaces. Light generated in the light emitting layer 11 reciprocates between the first end surface 56 and the second end surface 57 and is amplified by stimulated emission. The amplified light is extracted from the semiconductor layer 6 as laser light from one of either of the first end surface 56 and the second end surface 57.

In plan view, a peripheral edge of the apex portion 52 is positioned further inward than a peripheral edge of the base portion 53. That is, a planar area of a region surrounded by the peripheral edge of the apex portion 52 is less than a planar area of a region surrounded by the peripheral edge of the base portion 53. In this embodiment, the first side wall 54 and the second side wall 55 are downwardly inclined from the apex portion 52 toward the base portion 53. The first side wall 54 and the second side wall 55 may be formed perpendicular to the apex portion 52 instead.

An angle θ1 that the first side wall 54 forms with the first substrate main surface 3 inside the mesa structure 51 may be not less than 50° and not more than 90°. The angle θ1 may be not less than 50° and not more than 60°, not less than 60° and not more than 70°, not less than 70° and not more than 80°, or not less than 80° and not more than 90°. If the angle θ1 is less than 80°, light leaks out from the first side wall 54 of the mesa structure 51.

Therefore, the angle θ1 is preferably not less than 80°. In this case, the angle θ1 is preferably not less than 80° and not more than 82.5°, not less than 82.5° and not more than 85°, not less than 85° and not more than 87.5°, or not less than 87.5° and not more than 90°. The first side wall 54 may instead be formed in a mode where the angle θ1 increases gradually within a range of not less than 50° and not more than 90° from the apex portion 52 toward the base portion 53.

Similarly, an angle θ2 that the second side wall 55 forms with the first substrate main surface 3 inside the mesa structure 51 may be not less than 50° and not more than 90°. The angle θ2 may be not less than 50° and not more than 60°, not less than 60° and not more than 70°, not less than 70° and not more than 80°, or not less than 80° and not more than 90°. The angle θ2 is preferably not less than 80° and not more than 82.5°, not less than 82.5° and not more than 85°, not less than 85° and not more than 87.5°, or not less than 87.5° and not more than 90°. The second side wall 55 may instead be formed in a mode where the angle θ2 increases gradually within a range of not less than 50° and not more than 90° from the apex portion 52 toward the base portion 53.

A width in the second direction Y of the apex portion 52 may be not less than 10 μm and not more than 100 μm. The width of the apex portion 52 may be not less than 10 μm and not more than 20 μm, not less than 20 μm and not more than 40 μm, not less than 40 μm and not more than 60 μm, not less than 60 μm and not more than 80 μm, or not less than 80 μm and not more than 100 μm. The width in the second direction Y of the apex portion 52 is preferably not less than 20 μm and not more than 60 μm. A width in the second direction Y of the base portion 53 is the first width W1 of the light emitting region 31.

The pad region 32 has a pad mesa structure 61 of mesa shape (ridge shape) that projects from the first substrate main surface 3 toward the opposite side to the second substrate main surface 4. The pad mesa structure 61 is demarcated by the first trench 41 and the semiconductor side surfaces 8A, 8C, and 8D. The pad mesa structure 61 includes a pad apex portion 62, a pad base portion 63, and a pad side wall 64.

The pad apex portion 62 is formed by a portion of the semiconductor main surface 7. That is, the pad apex portion 62 of the pad mesa structure 61 is positioned on the same plane as the apex portion 52 of the mesa structure 51. Also, the pad apex portion 62 is formed by the p-type contact layer 12. The pad apex portion 62 is formed in parallel to the first substrate main surface 3 of the substrate 2.

The pad base portion 63 is preferably positioned at the substrate 2 side at least with respect to the light emitting layer 11. In this embodiment, the pad base portion 63 is formed by the substrate 2. The pad base portion 63 may instead be formed by the n-type buffer layer 10.

The pad side wall 64 is formed by the second side wall 44 of the first trench 41. The pad side wall 64 connects the pad apex portion 62 and the pad base portion 63. The pad side wall 64 is each formed by the p-type contact layer 12, the light emitting layer 11, the n-type buffer layer 10, and the substrate 2.

In plan view, a peripheral edge of the pad apex portion 62 is positioned further inward than a peripheral edge of the pad base portion 63. That is, a planar area of a region surrounded by the peripheral edge of the pad apex portion 62 is less than a planar area of a region surrounded by the peripheral edge of the pad base portion 63. In this embodiment, the pad side wall 64 is downwardly inclined from the pad apex portion 62 toward the pad base portion 63. The pad side wall 64 may be formed perpendicular to the pad apex portion 62 instead.

An angle θ3 that the pad side wall 64 forms with the first substrate main surface 3 inside the pad mesa structure 61 may be not less than 80° and not more than 90°. The angle θ3 may be not less than 80° and not more than 82.5°, not less than 82.5° and not more than 85°, not less than 85° and not more than 87.5°, or not less than 87.5° and not more than 90°.

A width in the second direction Y of the pad apex portion 62 may be not less than 120 μm and not more than 280 μm. The width of the pad apex portion 62 may be not less than 120 μm and not more than 140 μm, not less than 140 μm and not more than 160 μm, not less than 160 μm and not more than 180 μm, not less than 180 μm and not more than 200 μm, not less than 200 μm and not more than 220 μm, not less than 220 μm and not more than 240 μm, not less than 240 μm and not more than 260 μm, or not less than 260 μm and not more than 280 μm. A width in the second direction Y of the pad base portion 63 is the second width W2 of the pad region 32.

The outer region 33 has an outer mesa structure 71 of mesa shape (ridge shape) that projects from the first substrate main surface 3 toward the opposite side to the second substrate main surface 4. The outer mesa structure 71 is demarcated by the second trench 42 and the semiconductor side surfaces 8B, 8C, and 8D. The outer mesa structure 71 includes an outer apex portion 72, an outer base portion 73, and an outer side wall 74.

The outer apex portion 72 is formed by a portion of the semiconductor main surface 7. That is, the outer apex portion 72 of the outer mesa structure 71 is positioned on the same plane as the apex portion 52 of the mesa structure 51. Also, the outer apex portion 72 is formed by the p-type contact layer 12. The outer apex portion 72 is formed in parallel to the first substrate main surface 3 of the substrate 2.

The outer base portion 73 is preferably positioned at the substrate 2 side at least with respect to the light emitting layer 11. In this embodiment, the outer base portion 73 is formed by the substrate 2. The outer base portion 73 may instead be formed by the n-type buffer layer 10.

The outer side wall 74 is formed by the first side wall 46 of the second trench 42. The outer side wall 74 connects the outer apex portion 72 and the outer base portion 73. The outer side wall 74 is each formed by the p-type contact layer 12, the light emitting layer 11, the n-type buffer layer 10, and the substrate 2.

In plan view, a peripheral edge of the outer apex portion 72 is positioned further inward than a peripheral edge of the outer base portion 73. That is, a planar area of a region surrounded by the peripheral edge of the outer apex portion 72 is less than a planar area of a region surrounded by the peripheral edge of the outer base portion 73. In this embodiment, the outer side wall 74 is downwardly inclined from the outer apex portion 72 toward the outer base portion 73. The outer side wall 74 may be formed perpendicular to the outer apex portion 72 instead.

An angle θ4 that the outer side wall 74 forms with the first substrate main surface 3 inside the outer mesa structure 71 may be not less than 80° and not more than 90°. The angle θ4 may be not less than 80° and not more than 82.5°, not less than 82.5° and not more than 85°, not less than 85° and not more than 87.5°, or not less than 87.5° and not more than 90°.

A width in the second direction Y of the outer apex portion 72 may be not less than 10 μm and not more than 125 μm. The third width W3 may be not less than 10 μm and not more than 25 μm, not less than 25 μm and not more than 50 μm, not less than 50 μm and not more than 75 μm, not less than 75 μm and not more than 100 μm, or not less than 100 μm and not more than 125 μm. A width in the second direction Y of the outer base portion 73 is the third width W3 of the outer region 33.

Referring to FIG. 4, the mesa structure 51 includes a contact hole 79 that is formed in the apex portion 52. The contact hole 79 is formed in a surface layer portion of the p-type contact layer 12. In the apex portion 52, the contact hole 79 is recessed toward the base portion 53. In this embodiment, the contact hole 79 is formed at an interval from the peripheral edge of the apex portion 52.

The contact hole 79 extends as a band along the second direction Y in plan view. The contact hole 79 may be in communication with the first end surface 56 and the second end surface 57. The contact hole 79 may instead be formed inside a region surrounded by the peripheral edge of the apex portion 52 such as not to be in communication with the first end surface 56 and the second end surface 57.

The contact hole 79 may have a depth of not less than 1 Å and not more than 2000 Å. The depth may be not less than 1 Å and not more than 500 Å, not less than 500 Å and not more than 1000 Å, not less than 1000 Å and not more than 1500 Å, or not less than 1500 Å and not more than 2000 Å. The depth is preferably not less than 10 Å and not more than 1000 Å.

The semiconductor laser device 1 further includes an insulating layer 80 that covers the semiconductor main surface 7. In FIG. 2, the insulating layer 80 is shown with hatching for clarity. The insulating layer 80 is formed as a film on the semiconductor main surface 7. The insulating layer 80 may include silicon nitride or silicon oxide. In this embodiment, the insulating layer 80 includes silicon nitride.

The insulating layer 80 integrally includes a first region 81, a second region 82, and a third region 83. The first region 81 covers the light emitting region 31. The second region 82 covers the pad region 32. The third region 83 covers the outer region 33.

The first region 81 covers the apex portion 52, the base portion 53, the first side wall 54, and the second side wall 55 of the mesa structure 51. The second region 82 covers the pad apex portion 62, the pad base portion 63, and the pad side wall 64 of the pad mesa structure 61. A portion of the second region 82 that covers the pad apex portion 62 of the pad mesa structure 61 is formed at an interval inward from the first semiconductor side surface 8A. A peripheral edge of the semiconductor main surface 7 at the first semiconductor side surface 8A side is thereby exposed from the insulating layer 80 (second region 82).

The third region 83 covers the outer apex portion 72, the outer base portion 73, and the outer side wall 74 of the outer mesa structure 71. A portion of the third region 83 that covers the outer apex portion 72 is formed at an interval inward from the second semiconductor side surface 8B. A peripheral edge of the semiconductor main surface 7 at the second semiconductor side surface 8B side is thereby exposed from the insulating layer 80 (third region 83).

A contact opening 84 is formed in a portion of the insulating layer 80 (first region 81) that covers the apex portion 52 of the mesa structure 51. The contact opening 84 is in communication with the contact hole 79. The contact opening 84 exposes an inner wall of the contact hole 79. An inner wall of the contact opening 84 extends along the inner wall of the contact hole 79. The insulating layer 80 may expose the inner wall of the contact hole 79 instead. The insulating layer 80 may cover the inner wall of the contact hole 79 instead.

The semiconductor laser device 1 further includes a wiring electrode 88 that is formed on the insulating layer 80. The wiring electrode 88 is formed as a film on the insulating layer 80. The wiring electrode 88 includes an internal connection region 89 that penetrates through the insulating layer 80 and is electrically connected to the light emitting region 31 and an external connection region 90 that covers the pad region 32 across the insulating layer 80 and is externally connected to the lead wires 34.

More specifically, the wiring electrode 88 integrally includes a first wiring region 91 that covers the light emitting region 31, a second wiring region 92 that covers the pad region 32, and a third wiring region 93 that covers the outer region 33.

The first wiring region 91 covers the apex portion 52, the base portion 53, the first side wall 54, and the second side wall 55 of the mesa structure 51 across the first region 81 of the insulating layer 80. In the apex portion 52 of the mesa structure 51, the first wiring region 91 enters into the contact opening 84 of the insulating layer 80 and is electrically connected to the light emitting region 31.

More specifically, the first wiring region 91 is electrically connected to the p-type contact layer 12 inside the contact hole 79. The internal connection region 89 is formed by a portion of the first wiring region 91 that is connected to the p-type contact layer 12.

The second wiring region 92 covers the pad apex portion 62, the pad base portion 63, and the pad side wall 64 of the pad mesa structure 61 across the second region 82 of the insulating layer 80. A portion of the second wiring region 92 that covers the second region 82 is formed at an interval toward the light emitting region 31 side from a peripheral edge of the second region 82.

The peripheral edge of the second region 82 is thereby exposed from the second wiring region 92. The external connection region 90 that is externally connected to the lead wires 34 is formed by a portion of the second wiring region 92 that covers the pad apex portion 62 of the pad mesa structure 61.

The third wiring region 93 covers the outer apex portion 72, the outer base portion 73, and the outer side wall 74 of the outer mesa structure 71 across the third region 83 of the insulating layer 80. A portion of the third wiring region 93 that covers the outer apex portion 72 is formed at an interval toward the light emitting region 31 from a peripheral edge of the third region 83. The peripheral edge of the third region 83 is thereby exposed from the third wiring region 93.

The third wiring region 93 may be omitted. However, in view of stress that is applied to the light emitting region 31, it is preferable for the light emitting region 31 to have a structure that is sandwiched by the second wiring region 92 and the third wiring region 93. In this case, a balance can be achieved between stress applied to the light emitting region 31 due to the second wiring region 92 and stress applied to the light emitting region 31 due to the third wiring region 93.

The wiring electrode 88 may have a laminated structure in which a plurality of electrode layers are laminated. In this embodiment, the wiring electrode 88 includes a first electrode 95 and a second electrode 96 that are laminated in that order from the insulating layer 80 side.

The first electrode 95 may be a barrier electrode layer that includes at least one among a Pt (platinum) layer, a Ti (titanium layer), and a TiN (titanium nitride) layer. A thickness of the first electrode 95 may be not less than 10 nm and not more than 200 nm. The thickness of the first electrode 95 may be not less than 10 nm and not more than 50 nm, not less than 50 nm and not more than 100 nm, not less than 100 nm and not more than 150 nm, or not less than 150 nm and not more than 200 nm.

The second electrode 96 may be a low resistance electrode layer that includes an Au (gold) layer. A thickness of the second electrode 96 exceeds the thickness of the first electrode 95. The thickness of the second electrode 96 may be not less than 1 μm and not more than 5 μm. The thickness of the second electrode 96 may be not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, or not less than 4.5 μm and not more than 5 μm.

The semiconductor laser device 1 further includes an electrode 97 that is formed on the second substrate main surface 4. The electrode 97 is electrically connected to the substrate 2. In this embodiment, the electrode 97 covers an entire surface of the second substrate main surface 4. The electrode 97 may be formed on the second substrate main surface 4 such as to expose a peripheral edge portion of the second substrate main surface 4 instead. The electrode 97 may have a laminated structure that includes a plurality of electrode layers.

The electrode 97 may include at least one among an Ni (nickel) layer, an AuGe (aluminum-germanium alloy) layer, a Ti (titanium) layer, and an Au (gold) layer. The electrode 97 may have a laminated structure in which at least two among an Ni layer, an AuGe layer, a Ti layer, and an Au layer are laminated in any mode. The electrode 97 may include an AuGe layer, an Ni layer, a Ti layer, and an Au layer that are laminated in that order from the second substrate main surface 4 side.

Referring to FIG. 1 to FIG. 3, one or a plurality of the lead wires 34 are to be connected to the external connection region 90 (second wiring region 92) of the wiring electrode 88. The number of the lead wires 34 is arbitrary and not limited to a specific number. With this embodiment, an example where three lead wires 34A, 34B, and 34C are to be connected to the external connection region 90 (second wiring region 92) is illustrated.

Each lead wire 34 may include a bonding wire or a clip wire. In this embodiment, each lead wire 34 is constituted of a bonding wire. A clip wire has the same form as a bonding wire with the exception of being formed by a metal plate of comparatively wide width.

Each lead wire 34 may include at least one type of wire among a gold wire, a silver wire, an aluminum wire, and a copper wire as an example of a bonding wire. Each lead wire 34 is preferably constituted of a gold wire.

Each lead wire 34 includes a bonded portion 98 and a wire portion 99. The bonded portion 98 is a portion that is to be connected to the external connection region 90. If each lead wire 34 is constituted of a bonding wire, the bonded portion 98 may be referred to as a “wire ball,” a “stud bump,” etc. The wire portion 99 is a portion that extends as a line from the bonded portion 98 toward another connection object.

Referring to FIG. 2, the bonded portion 98 has a connection width WC in the second direction Y that exceeds the first width W1 of the light emitting region 31 (W1<WC). The connection width WC is less than the second width W2 of the pad region 32 (WC<W2). In this embodiment, the connection width WC is not less than the third width W3 of the outer region (W3≤WC). More specifically, the connection width WC exceeds the third width W3 (W3<WC).

The connection width WC may be not less than 50 μm but less than 300 μm. The connection width WC may be not less than 50 μm and not more than 75 μm, not less than 75 μm and not more than 100 μm, not less than 100 μm and not more than 125 μm, not less than 125 μm and not more than 150 μm, not less than 150 μm and not more than 200 μm, not less than 200 μm and not more than 250 μm, or not less than 250 μm but less than 300 μm. In this embodiment, the connection width WC is not less than 80 μm and not more than 150 μm.

It may be considered to connect the lead wires 34A to 34C on the light emitting region 31 instead. However, in this case, the bonded portion 98 has the connection width WC that exceeds the first width W1 of the light emitting region 31 (W1<WC) and therefore, a connection area of the bonded portion 98 with respect to the light emitting region 31 is insufficient and the lead wires 34A to 34C cannot be electrically connected to the light emitting region 31 appropriately. There is also a possibility of occurrence of a defect in the light emitting region 31 due to an external force or stress during connecting of the lead wires 34A to 34C.

Thus, with the semiconductor laser device 1, the pad region 32 to which the lead wires 34A to 34C are to be connected is formed in a region outside the light emitting region 31. Reduction of the light emitting region 31 can thereby be achieved appropriately without being restricted in design due to the lead wires 34A to 34C. Undesirable diffusion of current inside the mesa structure 51 can thus be suppressed and therefore, directivity of laser light can be improved.

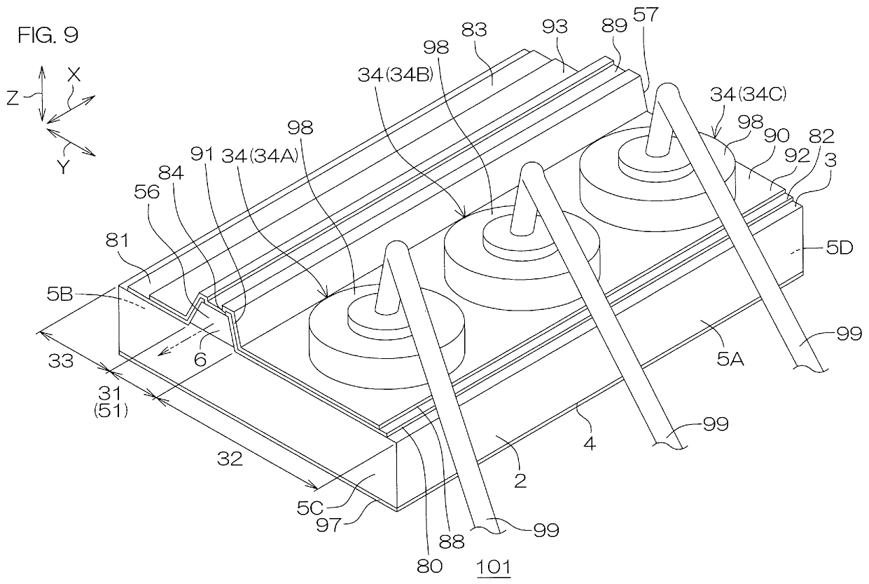

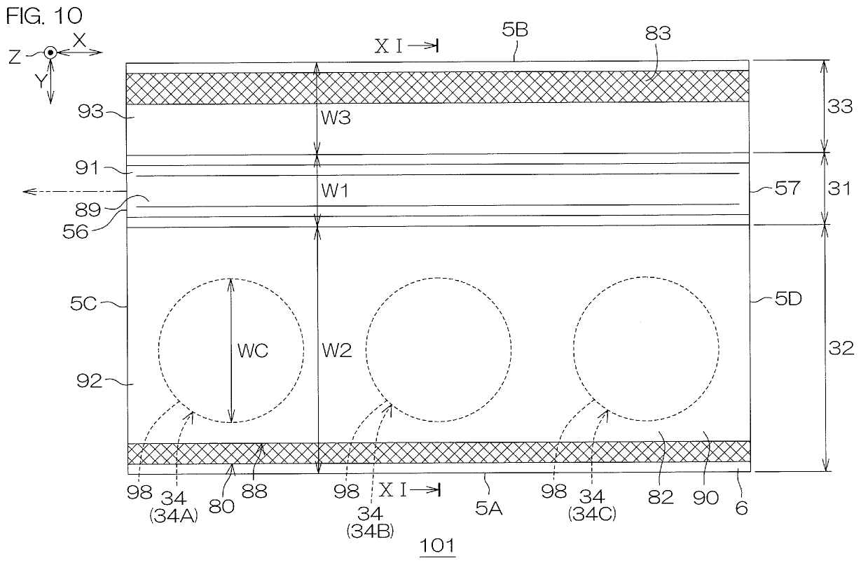

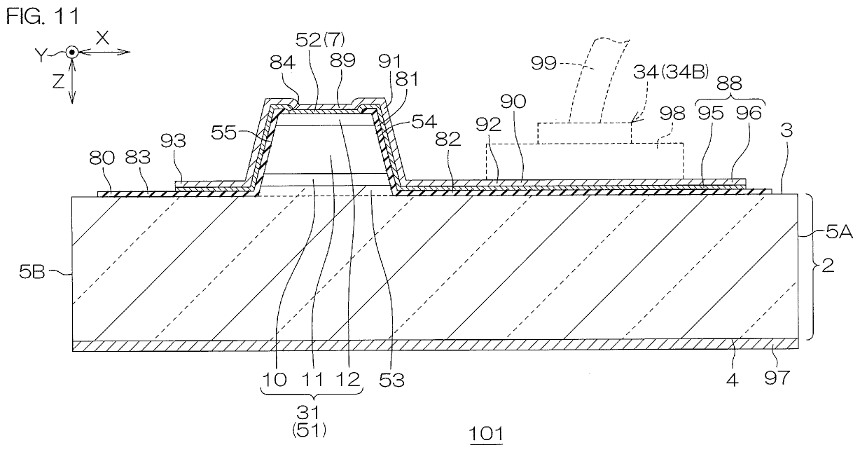

FIG. 9 is a perspective view of a semiconductor laser device 101 according to a second preferred embodiment of the present invention shown together with the lead wires 34 that are connected to the semiconductor laser device 101. FIG. 10 is a plan view of the semiconductor laser device 101 shown in FIG. 9. FIG. 11 is a sectional view taken along line XI-XI shown in FIG. 10. In the following, structures corresponding to the structures described for the semiconductor laser device 1 shall be provided with the same reference signs and description thereof shall be omitted.

With the semiconductor laser device 101, the pad region 32 does not have the pad mesa structure 61. The pad region 32 is formed at the base portion 53 side with respect to the apex portion 52 of the mesa structure 51 of the light emitting region 31. More specifically, the pad region 32 is formed on the first substrate main surface 3 of the substrate 2. A portion of the first substrate main surface 3 at which the pad region 32 is formed may be positioned at the second substrate main surface 4 side with respect to a portion of the first substrate main surface 3 that is positioned inside the mesa structure 51.

Also, with the semiconductor laser device 101, the outer region 33 does not have the outer mesa structure 71. The outer region 33 is formed at the base portion 53 side with respect to the apex portion 52 of the mesa structure 51 of the light emitting region 31. More specifically, the outer region 33 is formed on the first substrate main surface 3 of the substrate 2. A portion of the first substrate main surface 3 at which the outer region 33 is formed may be positioned at the second substrate main surface 4 side with respect to the portion of the first substrate main surface 3 that is positioned inside the mesa structure 51. The outer region 33 may be positioned on the same plane as the pad region 32.

In the pad region 32, the second region 82 of the insulating layer 80 covers the first substrate main surface 3. In the outer region 33, the third region 83 of the insulating layer 80 covers the first substrate main surface 3. The second wiring region 92 of the wiring electrode 88 covers the first substrate main surface 3 across the second region 82 of the insulating layer 80. The third wiring region 93 of the wiring electrode 88 covers the first substrate main surface 3 across the third region 83 of the insulating layer 80.

Even with the semiconductor laser device 101 described above, the same effects as the effects described for the semiconductor laser device 1 can be exhibited. With this embodiment, an example where the pad region 32 and the outer region 33 are formed by the first substrate main surface 3 was described. However, the pad region 32 and the outer region 33 may be formed respectively by the n-type buffer layer 10 instead.

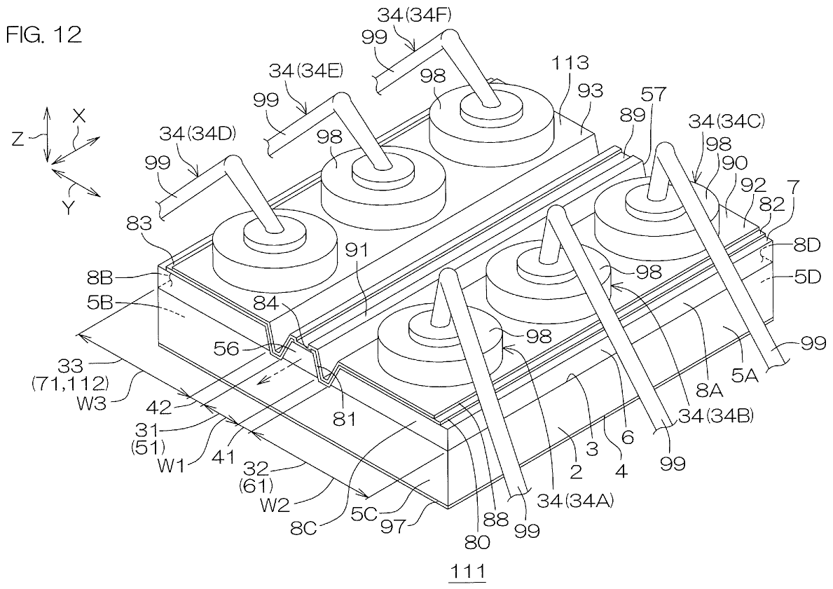

FIG. 12 is a perspective view of a semiconductor laser device 111 according to a third preferred embodiment of the present invention shown together with the lead wires 34 that are connected to the semiconductor laser device 111. In the following, structures corresponding to the structures described for the semiconductor laser device 1 shall be provided with the same reference signs and description thereof shall be omitted.

With the semiconductor laser device 1 described above, the outer region 33 has a structure to which the lead wires 34 are not to be connected. On the other hand, with the semiconductor laser device 111, the outer region 33 has the same structure as the pad region 32. That is, with the semiconductor laser device 111, the outer region 33 is formed as a second pad region 121 to which the lead wires 34 are to be connected.

The third width W3 of the outer region 33 exceeds the first width W1 of the light emitting region 31 (W1<W3). The third width W3 is preferably not less than ¼ and not more than ⅔ of the length L2 of the third substrate side surface 5C. The third width W3 is preferably not less than 1.5 times and not more than 4 times the first width W1. The third area S3 of the outer region 33 has exceeds the first area S1 in plan view (S1<S3).

The third width W3 may be not less than 150 μm and not more than 300 μm. The second width W2 may be not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, or not less than 275 μm and not more than 300 μm. The third width W3 is preferably not less than 150 μm and not more than 250 μm.

The third width W3 of the outer region 33 may be not less than the second width W2 of the pad region 32 (W2 W3) or may be less than the second width W2 of the pad region 32 (W3<W2). In this embodiment, the third width W3 is equal to the second width W2 (W2=W3).

In this embodiment, the portion of the third wiring region 93 of the wiring electrode 88 that covers the outer apex portion 72 of the outer mesa structure 71 forms, like the second wiring region 92, a second external connection region 113 that is externally connected to the lead wires 34.

One or a plurality of the lead wires 34 are to be connected respectively to the external connection region 90 (second wiring region 92) and the second external connection region 113 (third wiring region 93). The numbers of the lead wires 34 are arbitrary and not limited to specific numbers. With this embodiment, an example where the three lead wires 34A, 34B, and 34C are connected to the external connection region 90 (second wiring region 92) and three lead wires 34D, 34E, and 34F are connected to the second external connection region 113 (third wiring region 93) is illustrated.

Even with the semiconductor laser device 111 described above, the same effects as the effects described for the semiconductor laser device 1 can be exhibited. The structure in which the lead wires 34 are to be connected to the second external connection region 113 (third wiring region 93) can also be applied to the second preferred embodiment described above.

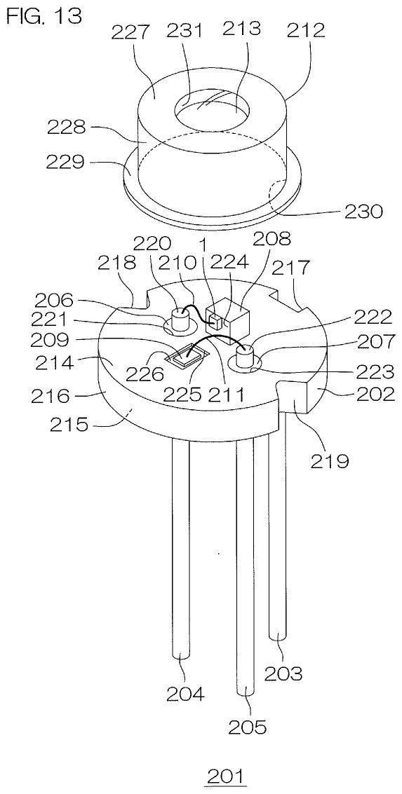

FIG. 13 is an exploded perspective view of a package 201 according to a first configuration example. In the following, an example where the semiconductor laser device 1 is installed in the package 201 shall be described. However, the semiconductor laser device 101 or the semiconductor laser device 111 may be installed in the package 201 in place of the semiconductor laser device 1.

Referring to FIG. 13, the package 201 is a semiconductor stem with which the semiconductor laser device 1 is housed inside a housing made of a metal. The package 201 includes the semiconductor laser device 1, a stem base 202, a first lead terminal 203, a second lead terminal 204, a third lead terminal 205, a first insulator 206, a second insulator 207, a heat sink 208, a photodiode 209, a first lead wire 210, a second lead wire 211, a cap 212, and a closing member 213.

The stem base 202 includes a plate member made of a metal (for example, made of iron). In this embodiment, the stem base 202 is formed to a disk shape. The stem base 202 has a first surface 214 at one side, a second surface 215 at another side, and a side surface 216 that connects the first surface 214 and the second surface 215.

A plurality (three in this embodiment) of notched portions are formed at intervals in an arbitrary region of the side surface 216 of the stem base 202. The plurality of notched portions include a first notched portion 217, a second notched portion 218, and a third notched portion 219.

The first notched portion 217 is recessed in a quadrilateral shape toward a central portion of the stem base 202. The second notched portion 218 and the third notched portion 219 are each recessed in a triangular shape toward the central portion of the stem base 202. The second notched portion 218 and the third notched portion 219 face each other across the central portion of the stem base 202. The first notched portion 217, the second notched portion 218, and the third notched portion 219 may indicate the positioning of the first lead terminal 203, the second lead terminal 204, and the third lead terminal 205.

The first lead terminal 203, the second lead terminal 204, and the third lead terminal 205 are provided on the second surface 215 of the stem base 202 at intervals from each other. The first lead terminal 203, the second lead terminal 204, and the third lead terminal 205 respectively extend as rods, columns, or shafts along a normal direction to the second surface 215.

The first lead terminal 203 is connected to the second surface 215 of the stem base 202. The first lead terminal 203 is thereby electrically connected to the stem base 202.

The second lead terminal 204 includes a lead-out portion 220 that is led out from the second surface 215 side of the stem base 202 to the first surface 214 side of the stem base 202. The lead-out portion 220 of the second lead terminal 204 is led out via a first penetrating hole 221 that is formed in the stem base 202.

The third lead terminal 205 includes a lead-out portion 222 that is led out from the second surface 215 side of the stem base 202 to the first surface 214 side of the stem base 202. The lead-out portion 222 of the third lead terminal 205 is led out via a second penetrating hole 223 that is formed in the stem base 202.

The first insulator 206 is interposed between the second lead terminal 204 and the stem base 202 inside the first penetrating hole 221. The first insulator 206 electrically insulates the second lead terminal 204 from the stem base 202. The first insulator 206 supports the second lead terminal 204.

The second insulator 207 is interposed between the third lead terminal 205 and the stem base 202 inside the second penetrating hole 223. The second insulator 207 electrically insulates the third lead terminal 205 from the stem base 202. The second insulator 207 supports the third lead terminal 205.

The heat sink 208 is provided on the first surface 214 of the stem base 202. The heat sink 208 includes a member of block shape or plate shape that is made of silicon, made of aluminum nitride, or made of a metal (for example, made of iron). The heat sink 208 may be formed integral to the first surface 214.

The heat sink 208 may be arranged at a peripheral edge portion side of the stem base 202 with respect to the central portion of the stem base 202 in a plan view as viewed from a normal direction to the first surface 214. The heat sink 208 has a first mounting surface 224. The first mounting surface 224 extends along the normal direction to the first surface 214. The first mounting surface 224 is directed toward the central portion of the stem base 202.

The semiconductor laser device 1 is mounted on the first mounting surface 224 of the heat sink 208. A sub-mount may be interposed between the semiconductor laser device 1 and the heat sink 208. The semiconductor laser device 1 irradiates laser light toward the normal direction to the first surface 214. The semiconductor laser device 1 is electrically connected to the first lead terminal 203 via the stem base 202.

The photodiode 209 is mounted on the first surface 214 of the stem base 202. The photodiode 209 is mounted in a region of the first surface 214 that faces the heat sink 208 across the central portion of the stem base 202.

More specifically, the photodiode 209 is mounted inside a recess portion 225 that is formed in the first surface 214. The recess portion 225 has a second mounting surface 226 formed on a bottom portion. The photodiode 209 is mounted on the second mounting surface 226. The photodiode 209 is electrically connected to the first lead terminal 203 via the stem base 202.

The first lead wire 210 corresponds to a lead wire 34 described above. The first lead wire 210 electrically connects the semiconductor laser device 1 and the second lead terminal 204. More specifically, the first lead wire 210 is connected to the external connection region 90 of the semiconductor laser device 1 and the lead-out portion 220 of the second lead terminal 204. The semiconductor laser device 1 is thereby electrically connected to the second lead terminal 204 via the first lead wire 210.

The semiconductor laser device 1 is thereby installed on the stem base 202 in a mode where a cathode is electrically connected to the first lead terminal 203 and an anode is electrically connected to the second lead terminal 204.

The second lead wire 211 may be a bonding wire. The second lead wire 211 electrically connects the photodiode 209 and the third lead terminal 205. More specifically, the second lead wire 211 is connected to the lead-out portion 222 of the third lead terminal 205. The photodiode 209 is thereby electrically connected to the third lead terminal 205 via the second lead wire 211.

The photodiode 209 is installed on the stem base 202 in a mode where a cathode is electrically connected to the third lead terminal 205 and an anode is electrically connected to the first lead terminal 203. The anode of the photodiode 209 is thereby electrically connected to the cathode of the semiconductor laser device 1 via the stem base 202.

The cap 212 includes a cylindrical member made of a metal (for example, made of iron). The cap 212 is mounted on the first surface 214 of the stem base 202. The cap 212 houses the heat sink 208, the semiconductor laser device 1, the photodiode 209, the lead-out portion 220 of the second lead terminal 204, the lead-out portion 222 of the third lead terminal 205, the first lead wire 210, and the second lead wire 211.

The cap 212 includes a facing wall 227, a side wall 228, and a flange 229. The facing wall 227 is formed to a plate shape (a disk shape in this embodiment). The facing wall 227 faces the first surface 214 of the stem base 202. The side wall 228 is formed to a cylindrical shape (a circular cylindrical shape in this embodiment) and is continuous to a peripheral edge of the facing wall 227. The side wall 228 demarcates an opening 230 at an opposite side to the facing wall 227.

The flange 229 protrudes to opposite sides to the opening 230 at an opening end of the opening 230. The flange 229 is formed to an annular shape (a circular annular shape in this embodiment) along the opening end of the opening 230. The cap 212 is fixed to the stem base 202 by the flange 229 being mounted on the first surface 214.

A light extraction window 231 is formed in the cap 212. The light extraction window 231 is formed in the facing wall 227. The light extraction window 231 guides the laser light generated by the semiconductor laser device 1 from inside the cap 212 to outside the cap 212.

The closing member 213 is a member that closes the light extraction window 231. The closing member 213 is preferably constituted of an insulator having translucency or an insulator that is transparent. In this embodiment, the closing member 213 is constituted of glass. The closing member 213 may be a lens arranged to increase directivity of the laser light. In this embodiment, the closing member 213 closes the light extraction window 231 from an inner side of the cap 212. The closing member 213 may close the light extraction window 231 from an outer side of the cap 212 instead.

With this embodiment, an example where the package 201 includes a photodiode 209 was described. However, the package 201 that does not include the photodiode 209 may be adopted instead. In this case, the third lead terminal 205 may be removed or may be left as an open terminal.

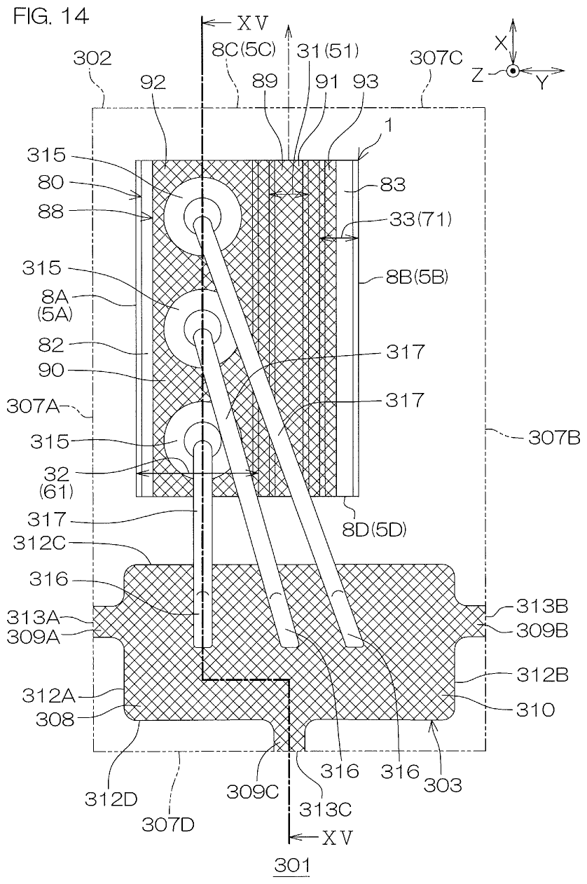

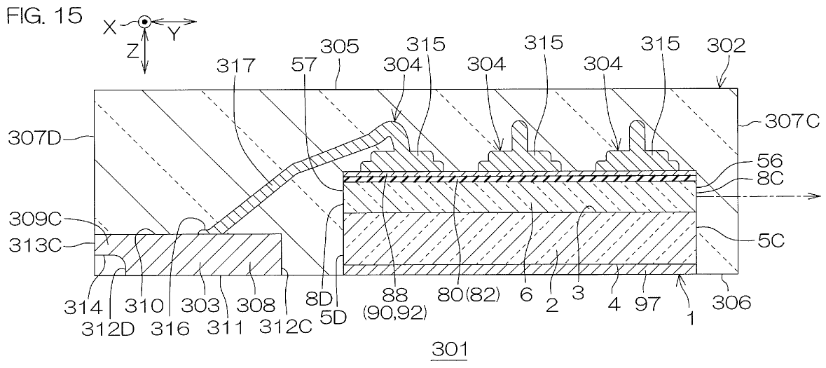

FIG. 14 is a plan view of a package 301 according to a second configuration example. FIG. 15 is a sectional view taken along line XV-XV shown in FIG. 14. In FIG. 14, a package main body 302 is shown transparently for clarification of the internal structure.

In the following, an example where the semiconductor laser device 1 is installed in the package 301 shall be described. However, the semiconductor laser device 101 or the semiconductor laser device 111 may be installed in the package 301 in place of the semiconductor laser device 1.

Referring to FIG. 14 and FIG. 15, the package 301 is a semiconductor package in which the semiconductor laser device 1 is sealed by a sealing resin. The package 301 includes the semiconductor laser device 1, the package main body 302, a terminal electrode 303, and lead wires 304. In FIG. 14, the wiring electrode 88 of the semiconductor laser device 1 and the terminal electrode 303 are shown with hatching.

The package main body 302 includes a transparent resin or a translucent resin. The package main body 302 may include an epoxy resin as an example of a transparent resin or a translucent resin. The package main body 302 is formed to a rectangular parallelepiped shape.

The package main body 302 includes a first surface 305 at one side, a second surface 306 at another side. and a plurality of side surfaces 307A, 307B, 307C, and 307D that connect the first surface 305 and the second surface 306. More specifically, the plurality of side surfaces 307A to 307D include a first side surface 307A, a second side surface 307B, a third side surface 307C, and a fourth side surface 307D.

The first surface 305 and the second surface 306 are formed to quadrilateral shapes (rectangular shapes in this embodiment) in a plan view as viewed from the normal direction Z thereto. The plurality of side surfaces 307A to 307D extend as planes along the normal direction Z.

The first side surface 307A and the second side surface 307B extend along the first direction X and face each other in the second direction Y. The first side surface 307A and the second side surface 307B form long sides of the package main body 302. The third side surface 307C and the fourth side surface 307D extend along the second direction Y and face each other in the first direction X. The third side surface 307C and the fourth side surface 307D form short sides of the package main body 302.

The terminal electrode 303 is arranged inside the package main body 302. In this embodiment, the terminal electrode 303 is arranged in a region inside the package main body 302 at the fourth side surface 307D side. The terminal electrode 303 may include a metal such as Fe, Cu, Ni, Al, etc.

A plating layer may be formed on an outer surface of the terminal electrode 303. The plating layer may have a single layer structure that includes a single plating layer. The plating layer may have a laminated structure that includes a plurality of plating layers. The plating layer may include at least one metal among Ti, TiN, Ni, Ag, Pd, Au, and Sn.

In this embodiment, the terminal electrode 303 integrally includes a terminal main body 308 and a plurality of extension portions 309A, 309B, and 309C. More specifically, the plurality of extension portions 309A to 309C include a first extension portion 309A, a second extension portion 309B, and a third extension portion 309C.

The terminal main body 308 is arranged inside the package main body 302 at intervals from the side surfaces 307A to 307D. The terminal main body 308 is formed to a rectangular parallelepiped shape. The terminal main body 308 includes a first terminal surface 310 at the first surface 305 side, a second terminal surface 311 at the second surface 306 side, and a plurality of terminal side surfaces 312A, 312B, 312C, and 312D that connect the first terminal surface 310 and the second terminal surface 311. More specifically, the plurality of terminal side surfaces 312A to 312D include a first terminal side surface 312A, a second terminal side surface 312B, a third terminal side surface 312C, and a fourth terminal side surface 312D.

The first terminal surface 310 and the second terminal surface 311 are formed to quadrilateral shapes (rectangular shapes extending along the second direction Y in this embodiment) in plan view. The second terminal surface 311 is exposed from the second surface 306 of the package main body 302. The second terminal surface 311 is formed as an external terminal that is externally connected to a connection object. The second terminal surface 311 may be formed flush with the second surface 306.

The plurality of terminal side surfaces 312A to 312D extend as planes along the normal direction Z. The first terminal side surface 312A faces the first side surface 307A of the package main body 302. The second terminal side surface 312B faces the second side surface 307B of the package main body 302. The third terminal side surface 312C faces the third side surface 307C of the package main body 302. The fourth terminal side surface 312D faces the fourth side surface 307D of the package main body 302.

The first terminal side surface 312A and the second terminal side surface 312B extend along the first direction X and face each other in the second direction Y. The first terminal side surface 312A and the second terminal side surface 312B form short sides of the terminal main body 308. The third terminal side surface 312C and the fourth terminal side surface 312D extend along the second direction Y and face each other in the first direction X. The third terminal side surface 312C and the fourth terminal side surface 312D form long sides of the terminal main body 308.

The first extension portion 309A is led out as a band from the first terminal side surface 312A toward the first side surface 307A. The first extension portion 309A has a first exposed portion 313A that is exposed from the first side surface 307A. The first exposed portion 313A may be formed flush with the first side surface 307A.

The second extension portion 309B is led out as a band from the second terminal side surface 312B toward the second side surface 307B. The second extension portion 309B has a second exposed portion 313B that is exposed from the second side surface 307B. The second extension portion 309B may be formed flush with the second side surface 307B.

The third extension portion 309C is led out as a band from the third terminal side surface 312C toward the fourth side surface 307D. The third extension portion 309C has a third exposed portion 313C that is exposed from the fourth side surface 307D. The third extension portion 309C may be formed flush with the fourth side surface 307D.

The plurality of extension portions 309A to 309C respectively form portions of the first terminal surface 310. In this embodiment, the plurality of extension portions 309A to 309C are formed at the terminal side surfaces 312A to 312D at intervals toward the first terminal surface 310 side from the second terminal surface 311.

The plurality of extension portions 309A to 309C thereby demarcate step portions 314 with the corresponding terminal side surfaces 312A to 312D. The step portions 314 are formed to shapes curved toward the terminal main body 308. Portions of the package main body 302 enter into the step portions 314. Detaching of terminal electrode 303 from the package main body 302 is thereby suppressed.

The semiconductor laser device 1 is arranged inside the package main body 302 at an interval toward the third side surface 307C side from the terminal electrode 303. The semiconductor laser device 1 is arranged inside the package main body 302 in an orientation where the first substrate main surface 3 of the substrate 2 is made to face the first surface 305 of the package main body 302.

The long sides (first substrate side surface 5A and second substrate side surface 5B) of the substrate 2 face the first side surface 307A and the second side surface 307B of the package main body 302. The short sides (third substrate side surface 5C and fourth substrate side surface 5D) of the substrate 2 face the third side surface 307C and the fourth side surface 307D of the package main body 302.

The semiconductor laser device 1 is arranged such that in plan view, the light emitting region 31 is positioned on a line joining a center of the third side surface 307C and a center of the fourth side surface 307D. The semiconductor laser device 1 is thereby biased to the first side surface 307A side in plan view. If the semiconductor laser device 111 is installed in place of the semiconductor laser device 1, the semiconductor laser device 111 may be sealed without being biased inside the package main body 302. The laser light generated by the semiconductor laser device 1 is extracted from the third side surface 307C of the package main body 302.

The electrode 97 of the semiconductor laser device 1 is exposed from the second surface 306 of the package main body 302. The electrode 97 is formed as an external terminal that is externally connected to a connection object. The electrode 97 may be formed flush with the second surface 306 of the package main body 302.

The plurality of lead wires 304 correspond to the lead wires 34A to 34C described above. The number of the lead wires 304 is arbitrary and not limited to a specific number. The plurality of lead wires 304 are each electrically connected to the external connection region 90 (wiring electrode 88) of the semiconductor laser device 1 and the first terminal surface 310 of the terminal electrode 303 inside the package main body 302.

The plurality of lead wires 304 each include a first bonded portion 315, a second bonded portion 316, and a wire portion 317. The first bonded portion 315 is connected to the external connection region 90 (wiring electrode 88) of the semiconductor laser device 1. The second bonded portion 316 is connected to the first terminal surface 310 of the terminal electrode 303. The wire portion 317 extends as a line from the first bonded portion 315 to the second bonded portion 316.

With this embodiment, an example where the electrode 97 of the semiconductor laser device 1 is exposed from the second surface 306 of the package main body 302 was described. However, the semiconductor laser device 1 may instead be arranged on a second terminal electrode that is exposed from the second surface 306 of the package main body 302 and forms a separate external terminal from the terminal electrode 303. In this case, the electrode 97 of the semiconductor laser device 1 is electrically connected to the second terminal electrode.

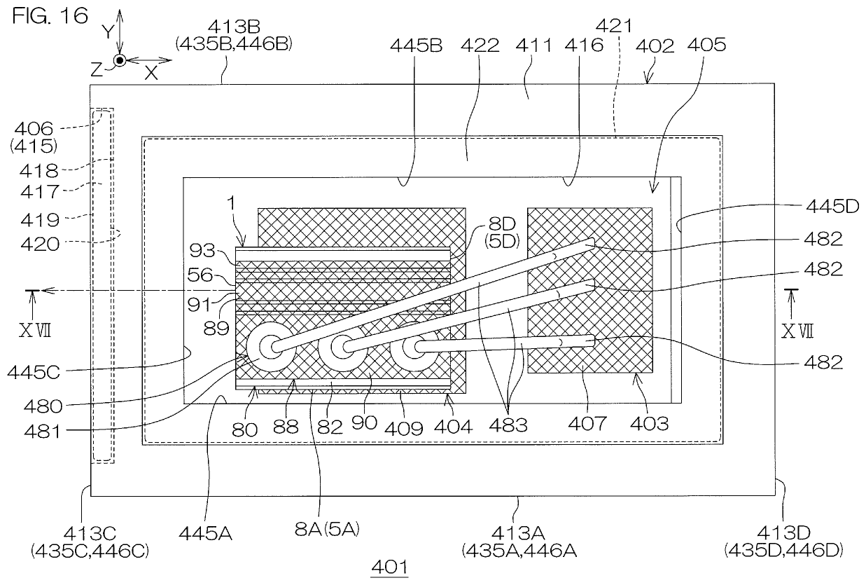

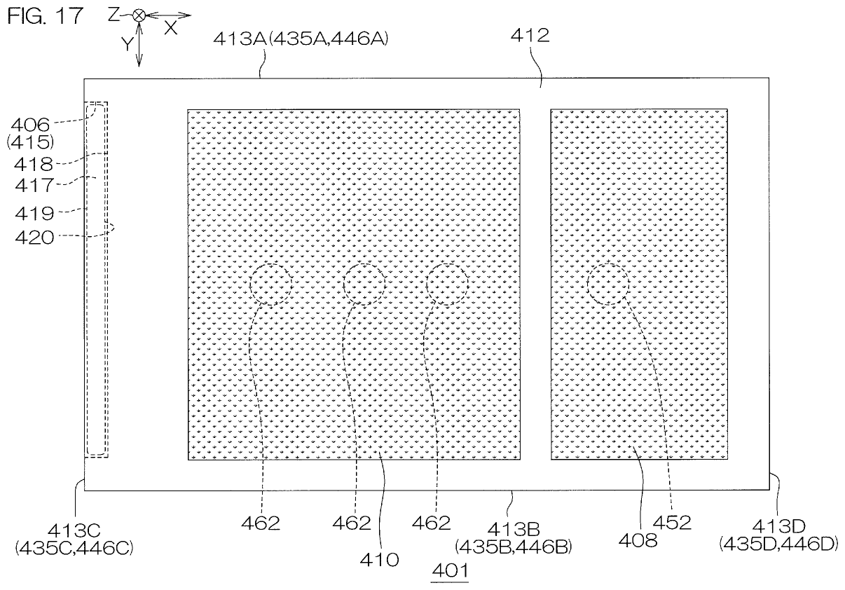

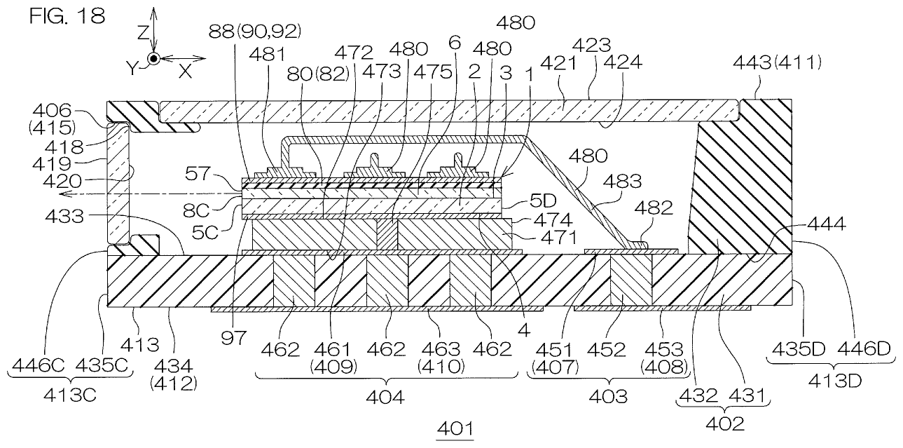

FIG. 16 is a plan view of a package 401 according to a third configuration example. FIG. 17 is a bottom view of the package 401 shown in FIG. 16. FIG. 18 is a sectional view taken along line XVIII-XVIII shown in FIG. 17.

In the following, an example where the semiconductor laser device 1 is installed in the package 401 shall be described. However, the semiconductor laser device 101 or the semiconductor laser device 111 may be installed in the package 401 in place of the semiconductor laser device 1.

Referring to FIG. 16 to FIG. 18, the package 401 is a semiconductor package in which the semiconductor laser device 1 is housed inside a case made of an insulating material. The package 401 includes a housing 402, the semiconductor laser device 1, a first wiring 403, and a second wiring 404. The housing 402 has an internal space 405 and a light extraction window 406. The semiconductor laser device 1 is housed inside the internal space 405. The light of the semiconductor laser device 1 is extracted from the light extraction window 406.

The first wiring 403 routed inside and outside the internal space 405. The first wiring 403 has a first end portion 407 that is positioned inside the internal space 405 and a second end portion 408 that is positioned outside the internal space 405. The first end portion 407 of the first wiring 403 is electrically connected to the wiring electrode 88 of the semiconductor laser device 1 inside the internal space 405. The second end portion 408 of the first wiring 403 is formed as an external terminal that is externally connected to a connection object.

The second wiring 404 routed inside and outside the internal space 405. The second wiring 404 has a first end portion 409 that is positioned inside the internal space 405 and a second end portion 410 that is positioned outside the internal space 405. The first end portion 409 of the second wiring 404 is electrically connected to the electrode 97 of the semiconductor laser device 1 inside the internal space 405. The second end portion 410 of the second wiring 404 is formed as an external terminal that is externally connected to a connection object. The specific structure of the package 401 shall now be described.

The casing 402 is formed to a rectangular parallelepiped shape. In this embodiment, the casing 402 is formed of an insulator. The casing 402 has a first main surface 411 at one side, a second main surface 412 at another side, and a plurality of side surfaces 413A, 413B, 413C, and 413D that connect the first main surface 411 and the second main surface 412. More specifically, the plurality of side surfaces 413A to 413D include a first side surface 413A, a second side surface 413B, a third side surface 413C, and a fourth side surface 413D.

The first main surface 411 and the second main surface 412 are formed to quadrilateral shapes (rectangular shapes in this embodiment) in a plan view as viewed from the normal direction Z thereto. The plurality of side surfaces 413A to 413D extend as planes along the normal direction Z.

The first side surface 413A and the second side surface 413B extend along the first direction X and face each other in the second direction Y. The first side surface 413A and the second side surface 413B form long sides of the casing 402. The third side surface 413C and the fourth side surface 413D extend along the second direction Y and face each other in the first direction X. The third side surface 413C and the fourth side surface 413D form short sides of the casing 402.

The internal space 405 for housing the semiconductor laser device 1 is demarcated in an interior of the casing 402. In this embodiment, the internal space 405 is demarcated in a quadrilateral shape in plan view. A planar shape of the internal space 405 is arbitrary and is not limited to a specific shape.

A first window 415 that is in communication with the internal space 405 is demarcated in the third side surface 413C. The first window 415 is formed as the light extraction window 406 for extracting the light of the semiconductor laser device 1. The first window 415 is demarcated in a quadrilateral shape in a front view of viewing the third side surface 413C from the front. In this embodiment, the first window 415 is demarcated in a rectangular shape that extends along the second direction Y. That is, the third side surface 413C is formed to a quadrilateral annular shape (a rectangular annular shape in this embodiment) in front view by the first window 415.

A second window 416 that is in communication with the internal space 405 is demarcated in the first main surface 411. The semiconductor laser device 1 is housed in the internal space 405 via the second window 416. In this embodiment, the second window 416 is demarcated in a quadrilateral shape in plan view.

That is, the first main surface 411 is formed to a quadrilateral annular shape (a rectangular annular shape in this embodiment) in front view by the second window 416. A planar shape of the second window 416 is arbitrary and is not limited to a specific shape. The planar shape of the second window 416 does not necessarily have to match (conform to) the planar shape of the internal space 405.

The package 401 includes a first closing member 417 that closes the first window 415 (internal space 405). The first closing member 417 is constituted of a plate member. The first closing member 417 is preferably constituted of a member that transmits the light of the semiconductor laser device 1. The first closing member 417 is preferably constituted of an insulator having translucency or an insulator that is transparent.

The first closing member 417 is mounted on the third side surface 413C of the casing 402. More specifically, the first closing member 417 is mounted on a first supporting portion 418 that is formed in a periphery of the first window 415. In this embodiment, the first supporting portion 418 is demarcated by a recess that is formed in a surface layer portion of the third side surface 413C such as to be in communication with the first window 415. In this embodiment, the first supporting portion 418 (recess) is demarcated in a quadrilateral annular shape (a rectangular annular shape in this embodiment) that surrounds the first window 415 in plan view.

The first closing member 417 includes a first plate surface 419 at the third side surface 413C side and a second plate surface 420 at the fourth side surface 413D side. The first plate surface 419 and the second plate surface 420 have flat surfaces that are parallel to the third side surface 413C. The first plate surface 419 may project further laterally than the third side surface 413C. The first plate surface 419 may be positioned at the fourth side surface 413D side with respect to the third side surface 413C. The first plate surface 419 may be positioned on the same plane as the third side surface 413C.

The second plate surface 420 is mounted on the first supporting portion 418 in a region at the fourth side surface 413D side with respect to the third side surface 413C. The second plate surface 420 may be mounted on the first supporting portion 418 via an adhesive. The adhesive may include a resin (for example, an infrared curable resin).

The package 401 includes a second closing member 421 that closes the second window 416 (internal space 405). The second closing member 421 is constituted of a plate member. Although a material of the second closing member 421 is not restricted in particular, it preferably includes an insulator. The insulator may be an inorganic insulator or an organic insulator. The second closing member 421 may have a light blocking property.

The second closing member 421 is mounted on the first main surface 411 of the casing 402. More specifically, the second closing member 421 is mounted on a second supporting portion 422 that is formed in a periphery of the second window 416. In this embodiment, the second supporting portion 422 is demarcated by a recess that is formed in a surface layer portion of the first main surface 411 such as to be in communication with the second window 416. In this embodiment, the second supporting portion 422 (recess) is demarcated in a quadrilateral annular shape that surrounds the second window 416 in plan view.

The second closing member 421 includes a first plate surface 423 at the first main surface 411 side and a second plate surface 424 at the second main surface 412 side. The first plate surface 423 and the second plate surface 424 have flat surfaces that are parallel to the first main surface 411. The first plate surface 423 may project further upward than the first main surface 411. The first plate surface 423 may be positioned at the second main surface 412 side with respect to the first main surface 411. The first plate surface 423 may be positioned on the same plane as the first main surface 411.

The second plate surface 424 is mounted on the second supporting portion 422 in a region at the second main surface 412 side with respect to the first main surface 411. The second plate surface 424 may be mounted on the second supporting portion 422 via an adhesive. The adhesive may include a resin (for example, an infrared curable resin).

More specifically, the casing 402 includes a base layer 431 and a frame layer 432. The first main surface 411 of the casing 402 is formed by the frame layer 432. The second main surface 412 of the casing 402 is formed by the base layer 431. The side surfaces 413A to 413D of the casing 402 are formed by the base layer 431 and the frame layer 432.

The base layer 431 is constituted of a plate member of rectangular parallelepiped shape. The base layer 431 includes a first surface 433 at the first main surface 411 side, a second surface 434 at the second main surface 412 side, and a plurality of side surfaces 435A, 435B, 435C, and 435D that connect the first surface 433 and the second surface 434. More specifically, the plurality of side surfaces 435A to 435D include a first side surface 435A, a second side surface 435B, a third side surface 435C, and a fourth side surface 435D.

The first surface 433 forms a portion of the internal space 405. The second surface 434 forms the second main surface 412 of the casing 402. The side surfaces 435A to 435D respectively form portions of the side surfaces 413A to 413D of the casing 402.

The base layer 431 includes one of either or both of an inorganic insulator and an organic insulator. The base layer 431 may include at least one type of material among silicon oxide, silicon nitride, aluminum oxide, and aluminum nitride as an example of an inorganic insulator.

The base layer 431 may include one of either or both of a photosensitive resin and a thermosetting resin as an example of an organic insulator. The base layer 431 may include at least one type of material among an epoxy resin, a polyimide resin, a polybenzoxazole resin, an acrylic resin, and a silicone resin as an example of an organic insulator. In this embodiment, the base layer 431 is constituted of a glass epoxy substrate with which glass fibers are impregnated with epoxy resin.

The frame layer 432 is formed to an annular shape (a quadrilateral annular shape in this embodiment) that surrounds an inner region of the base layer 431 in plan view and demarcates the internal space 405 with the first surface 433 of the base layer 431. The frame layer 432 includes a first surface 443 at the first main surface 411 side, a second surface 444 at the second main surface 412 side, a plurality of inner walls 445A, 445B, 445C, and 445D that connect the first surface 443 and the second surface 444, and a plurality of outer walls 446A, 446B, 446C, and 446D that connect the first surface 443 and the second surface 444.

More specifically, the plurality of inner walls 445A to 445D include a first inner wall 445A, a second inner wall 445B, a third inner wall 445C, and a fourth inner wall 445D. The inner walls 445A to 445D demarcate the internal space 405 with the first surface 433 of the base layer 431.

More specifically, the plurality of outer walls 446A to 446D include a first outer wall 446A, a second outer wall 446B, a third outer wall 446C, and a fourth outer wall 446D. The outer walls 446A to 446D respectively form portions of the side surfaces 413A to 413D of the casing 402.

The first window 415 and the first supporting portion 418 (recess) described above are formed in a portion of the frame layer 432 that forms the third side surface 413C of the casing 402. The second window 416 and the second supporting portion 422 (recess) described above are formed in the first surface 443 of the frame layer 432.

The frame layer 432 includes one of either or both of an inorganic insulator and an organic insulator. The frame layer 432 may include at least one type of material among silicon oxide, silicon nitride, aluminum oxide, and aluminum nitride as an example of an inorganic insulator.

The frame layer 432 may include one of either or both of a photosensitive resin and a thermosetting resin as an example of an organic insulator. The frame layer 432 may include at least one type of material among an epoxy resin, a polyimide resin, a polybenzoxazole resin, an acrylic resin, and a silicone resin as an example of an organic insulator. In this embodiment, the frame layer 432 is constituted of an epoxy resin that is molded in a metal mold.

The first wiring 403 penetrates through the casing 402 from the internal space 405 and is led out to the second main surface 412. More specifically, the first wiring 403 passes through an interior of the base layer 431 from above the first surface 433 of the base layer 431 and is led out onto the second surface 434 of the base layer 431.

The first wiring 403 includes a first connection portion 451, a first penetrating portion 452, and a first external terminal portion 453. The first connection portion 451 forms the first end portion 407 of the first wiring 403. The first external terminal portion 453 forms the second end portion 408 of the first wiring 403.

The first connection portion 451 is formed in a region of the first surface 433 of the base layer 431 at the fourth side surface 413D side of the casing 402. The first connection portion 451 is formed as a film. The first connection portion 451 is formed to a quadrilateral shape in plan view. A planar shape of the first connection portion 451 is arbitrary and is not limited to a specific shape. The first connection portion 451 may include at least one type of material among Cu, Ni, Ti, and Au.

The first penetrating portion 452 penetrates through the base layer 431 from the first surface 433 to the second surface 434 and is exposed from the first surface 433 and the second surface 434. The first penetrating portion 452 is overlapped with the first connection portion 451 in plan view. The first penetrating portion 452 is electrically connected to the first connection portion 451 at a portion exposed from the first surface 433 of the base layer 431.

The first penetrating portion 452 is formed to a circular shape in plan view. A planar shape of the first penetrating portion 452 is arbitrary and is not limited to a specific shape. The first connection portion 451 may include at least one type of material among Cu, Ni, Ti, and Au.

The first external terminal portion 453 is formed in a region of the second surface 434 of the base layer 431 at the fourth side surface 413D side of the casing 402. The first external terminal portion 453 is formed as a film. The first external terminal portion 453 covers the first penetrating portion 452. The first external terminal portion 453 is electrically connected to the first penetrating portion 452.

The first external terminal portion 453 is formed to a quadrilateral shape in plan view. A planar shape of the first external terminal portion 453 is arbitrary and is not limited to a specific shape. The first external terminal portion 453 may include at least one type of material among Cu, Ni, Ti, and Au.

The second wiring 404 penetrates through the casing 402 from the internal space 405 and is led out to the second main surface 412. More specifically, the second wiring 404 passes through the interior of the base layer 431 from above the first surface 433 of the base layer 431 and is led out onto the second surface 434 of the base layer 431.

The second wiring 404 includes a second connection portion 461, a plurality of second penetrating portions 462, and a second external terminal portion 463. The second connection portion 461 forms the first end portion 409 of the second wiring 404. The second external terminal portion 463 forms the second end portion 410 of the second wiring 404.

The second connection portion 461 is formed in a region of the first surface 433 of the base layer 431 at the third side surface 413C side of the casing 402 at an interval from the first connection portion 451. The second connection portion 461 is formed as a film. The second connection portion 461 is formed to a quadrilateral shape in plan view. A planar shape of the second connection portion 461 is arbitrary and is not limited to a specific shape. The second connection portion 461 may include at least one type of material among Cu, Ni, Ti, and Au.

The plurality of second penetrating portions 462 penetrate through the base layer 431 from the first surface 433 to the second surface 434 and are exposed from the first surface 433 and the second surface 434. In this embodiment, the plurality of second penetrating portions 462 are formed at intervals along the first direction X. The number and positioning of the plurality of second penetrating portions 462 are arbitrary and not limited to a specific number and positioning.

The plurality of second penetrating portions 462 are overlapped with the second connection portion 461 in plan view. The plurality of second penetrating portions 462 are electrically connected to the second connection portion 461 at portions exposed from the second surface 434 of the base layer 431.

The second penetrating portions 462 are formed to circular shapes in plan view. Planar shapes of the second penetrating portions 462 are arbitrary and are not limited to specific shapes. The second connection portion 461 may include at least one type of material among Cu, Ni, Ti, and Au.

The second external terminal portion 463 is formed in a region of the second surface 434 of the base layer 431 at the third side surface 413C side of the casing 402 at an interval from the first external terminal portion 453. The second external terminal portion 463 is formed as a film. The second external terminal portion 463 covers the plurality of second penetrating portions 462. The second external terminal portion 463 is electrically connected to the plurality of second penetrating portions 462.

The second external terminal portion 463 is formed to a quadrilateral shape in plan view. A planar shape of the second external terminal portion 463 is arbitrary and is not limited to a specific shape. The second external terminal portion 463 may include at least one type of material among Cu, Ni, Ti, and Au.

In this embodiment, the package 401 further includes a sub-mount 471. The sub-mount 471 is constituted of a plate member that is formed to a rectangular parallelepiped shape. The sub-mount 471 includes a first surface 472 at the first main surface 411 side, a second surface 473 at the second main surface 412 side, and a side surface 474 that connects the first surface 472 and the second surface 473. The second surface 473 of the sub-mount 471 is connected to the second connection portion 461 of the second wiring 404. The sub-mount 471 may include at least one type of material among Si, GaN, SiC, and AlN.

The sub-mount 471 includes one or a plurality of penetrating wirings 475. The penetrating wiring 475 penetrates through the sub-mount 471 from the first surface 472 to the second surface 473 and is exposed from the first surface 472 and the second surface 473. The penetrating wiring 475 is electrically connected to the second connection portion 461 of the second wiring 404 at the second surface 473.

The penetrating wiring 475 is formed to a circular shape in plan view. A planar shape of the penetrating wiring 475 is arbitrary and is not limited to a specific shape. The penetrating wiring 475 may include at least one type of substance among Cu, Ni, Ti, and Au.

The semiconductor laser device 1 is arranged on the first surface 472 of the sub-mount 471 in an orientation where the first substrate main surface 3 of the substrate 2 is made to face the first main surface 411 of the casing 402. The long sides (first substrate side surface 5A and second substrate side surface 5B) of the substrate 2 face the first side surface 413A and the second side surface 413B of the casing 402. The short sides (third substrate side surface 5C and fourth substrate side surface 5D) of the substrate 2 face the third side surface 413C and the fourth side surface 413D of the casing 402.

The electrode 97 of the semiconductor laser device 1 is electrically connected to the penetrating wiring 475 of the sub-mount 471. The semiconductor laser device 1 is thereby electrically connected to the second wiring 404 via the penetrating wiring 475. The electrode 97 may be connected to the penetrating wiring 475 via a conductive bonding material. The conductive bonding material may be a metal paste or solder.

A light extraction surface (the third substrate side surface 5C (first end surface 56) in this embodiment) of the semiconductor laser device 1 projects from the sub-mount 471 to the third side surface 413C of the casing 402 in plan view. The first substrate main surface 3 of the substrate 2 faces the first surface 433 of the base layer 431 in the normal direction Z.

By this structure, the laser light of the semiconductor laser device 1 is extracted from a region outside the sub-mount 471. Interference of the laser light (reflection, absorption, etc., of light) by the sub-mount 471 can thus be suppressed. Obviously, an entire area of the semiconductor laser device 1 may be positioned on the sub-mount 471 instead.

The semiconductor laser device 1 is arranged such that in plan view, the light emitting region 31 is positioned on a line joining a center of the third side surface 413C and a center of the fourth side surface 413D. The semiconductor laser device 1 is thereby biased to the first side surface 413A side in plan view. If the semiconductor laser device 111 is installed in place of the semiconductor laser device 1, the semiconductor laser device 111 may be arranged inside the casing 402 without being biased.

The package 401 further includes one or a plurality (three in this embodiment) of lead wires 480. The plurality of lead wires 480 correspond to the lead wires 34A to 34C described above. The number of the lead wires 480 is arbitrary and not limited to a specific number. The plurality of lead wires 480 are each electrically connected to the external connection region 90 (wiring electrode 88) of the semiconductor laser device 1 and the first connection portion 451 of the first wiring 403.

More specifically, the plurality of lead wires 480 each include a first bonded portion 481, a second bonded portion 482, and a wire portion 483. The first bonded portion 481 is connected to the external connection region 90 (wiring electrode 88) of the semiconductor laser device 1. The second bonded portion 482 is connected to the first connection portion 451 of the first wiring 403. The wire portion 483 extends as a line from the first bonded portion 481 to the second bonded portion 482. The semiconductor laser device 1 is thereby electrically connected to the first wiring 403 via the lead wires 480.

Although preferred embodiments of the present invention have been described above, the present invention can be implemented in yet other embodiments.

With each of the preferred embodiments described above, an example where the semiconductor layer 6 includes three light emitting unit layers 13 and two tunnel junction layers 14 was described. However, the number of the light emitting unit layers 13 is arbitrary and not limited to three. One, two, three, or more than three light emitting unit layers 13 may be formed. Also, the number of the tunnel junction layers 14 is adjusted in accordance with the number of the light emitting unit layers 13 and is not limited to two.

In each of the preferred embodiments described above, a structure in which the conductivity types of the respective semiconductor portions are inverted may be adopted. That is, a p-type portion may be of an n-type and an n-type portion may be of a p-type.

The present application corresponds to Japanese Patent Application No. 2019-042890 filed on Mar. 8, 2019 in the Japan Patent Office, and the entire disclosure of this application is incorporated herein by reference. While preferred embodiments of the present invention have been described in detail, these are merely specific examples used to clarify the technical contents of the present invention and the present invention should not be interpreted as being limited to these specific examples and the scope of the present invention is to be limited only by the appended claims.

### REFERENCE SIGNS LIST

1 semiconductor laser device
6 semiconductor layer
10 n-type buffer layer
11 light emitting layer
12 p-type contact layer
13 light emitting unit layer
13A first light emitting unit layer
13B second light emitting unit layer
13C third light emitting unit layer
14 tunnel junction layer
14A first tunnel junction layer
14B second tunnel junction layer
31 light emitting region
32 pad region
34 lead wire
34A lead wire
34B lead wire
34C lead wire
51 mesa structure
52 apex portion
53 base portion
54 first side wall
55 second side wall
61 pad mesa structure
62 pad apex portion
63 pad base portion
64 pad side wall
88 wiring electrode
89 internal connection region
90 external connection region
101 semiconductor laser device
111 semiconductor laser device
201 package (semiconductor stem)
301 package (semiconductor package)
401 package (semiconductor package)
W1 first width
W2 second width
W3 third width
WC connection width

1. A semiconductor laser device comprising:
a semiconductor layer that includes a light emitting region having a first width and a pad region formed in a region outside the light emitting region and having a second width exceeding the first width;
an insulating layer that covers the light emitting region and the pad region; and
a wiring electrode that has an internal connection region penetrating through the insulating layer and electrically connected to the light emitting region and an external connection region that covers the pad region across the insulating layer and is to be externally connected to a lead wire.

2. The semiconductor laser device according to claim 1, wherein the external connection region is to be externally connected to the lead wire that has a connection width exceeding the first width.

3. The semiconductor laser device according to claim 1, wherein the light emitting region extends as a band along a first direction and has the first width in a second direction that is orthogonal to the first direction, and
the pad region faces the light emitting region in the second direction, is formed in the region outside the light emitting region such as to extend as a band along the first direction, and has the second width in the second direction.

4. The semiconductor laser device according to claim 1, wherein the light emitting region includes a mesa structure that has an apex portion, a base portion, and a side wall connecting the apex portion and the base portion and is demarcated in a mesa shape,
the pad region is formed to be electrically separated from the mesa structure, and
the internal connection region of the wiring electrode is electrically connected to the apex portion of the mesa structure.

5. The semiconductor laser device according to claim 4, wherein the side wall of the mesa structure is downwardly inclined from the apex portion toward the base portion.

6. The semiconductor laser device according to claim 4, wherein the mesa structure includes a light emitting unit layer that includes a first semiconductor layer of a first conductivity type formed at the base portion side, a second semiconductor layer of a second conductivity type formed at the apex portion side, and an active layer interposed between the first semiconductor layer and the second semiconductor layer, and
the internal connection region of the wiring electrode is electrically connected to the second semiconductor layer.

7. The semiconductor laser device according to claim 6, wherein the mesa structure includes a plurality of the light emitting unit layers that are laminated from the base portion side toward the apex portion side and a tunnel junction layer that is interposed between the plurality of light emitting unit layers.

8. The semiconductor laser device according to claim 4, wherein the pad region includes a pad mesa structure that has a pad apex portion, a pad base portion, and a pad side wall connecting the pad apex portion and the pad base portion and is demarcated in a mesa shape, and
the external connection region of the wiring electrode covers the pad apex portion of the pad mesa structure.

9. The semiconductor laser device according to claim 8, wherein the pad side wall of the pad mesa structure is downwardly inclined from the pad apex portion toward the pad base portion.

10. The semiconductor laser device according to claim 4, wherein the pad region is formed at the base portion side with respect to the apex portion of the mesa structure.

11. The semiconductor laser device according to claim 1, further comprising:
a substrate that has a first main surface at one side and a second main surface at another side; and
wherein the semiconductor layer is formed on the first main surface of the substrate.

12. The semiconductor laser device according to claim 11, wherein the light emitting region is formed shifted from a center of the substrate in plan view.

13. The semiconductor laser device according to claim 11, further comprising:
an electrode that is formed on the second main surface of the substrate and is electrically connected to the semiconductor layer via the substrate.

14. A semiconductor stem comprising:
a stem base that has a first surface at one side and a second surface at another side and is made of a metal;
a first terminal that is connected to the second surface of the stem base;
a second terminal that penetrate through the stem base from the second surface of the stem base and is led out to the first surface;
the semiconductor laser device according to claim 1 that is arranged on the first surface of the stem base and is electrically connected to the first terminal via the stem base; and
a lead wire that is connected to the second terminal and the external connection region of the wiring electrode of the semiconductor laser device.

15. A semiconductor package comprising:
a package main body that includes a transparent resin or a translucent resin;
a terminal electrode sealed inside the package main body;
the semiconductor laser device according to claim 1 that is sealed inside the package main body at an interval from the terminal electrode; and
a lead wire that is sealed inside the package main body and is connected to the terminal electrode and the external connection region of the wiring electrode of the semiconductor laser device.

16. The semiconductor package according to claim 15, wherein the semiconductor laser device is arranged shifted from a center of the package main body in plan view.

17. A semiconductor package comprising:
a casing that has an internal space;
a first wiring that is routed inside and outside the casing;
a second wiring that is routed inside and outside the casing in a state of being electrically insulated from the first wiring;
the semiconductor laser device according to claim 1 that is arranged on the second wiring inside the internal space and is electrically connected to the second wiring; and
a lead wire that is connected to the first wiring and the external connection region of the wiring electrode of the semiconductor laser device.

18. The semiconductor package according to claim 17, wherein the semiconductor laser device is arranged shifted from a center of the casing in plan view.
